(19) United States
(12) Patent Application Publication
(10) Pub. No.: US 2025/0386504 A1
(43) Pub. Date: Dec. 18, 2025

(54) SEMICONDUCTOR DEVICE, MANUFACTURING METHOD THEREOF, MEMORY SYSTEM AND ELECTRONICS

(71) Applicant: Yangtze Memory Technologies Co., Ltd., Wuhan (CN)

(72) Inventors: Zhengliang Xia, Wuhan (CN); Zongliang Huo, Wuhan (CN); Wenbin Zhou, Wuhan (CN); Sizhe Li, Wuhan (CN); Jiaji Wu, Wuhan (CN)

(21) Appl. No.: 19/228,618

(22) Filed: Jun. 4, 2025

Related U.S. Application Data
(60) Provisional application No. 63/661,018, filed on Jun. 17, 2024.

(30) Foreign Application Priority Data
Jul. 19, 2024 (CN) 202410982899.5

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

The present disclosure provides a semiconductor device, a manufacturing method thereof, a memory system and electronics, relates to the technical field of semiconductor chips, and aims at improving the problem of the higher cost caused by the fact that many metal lines are used for a first bit line and a second bit line.

### CROSS-REFERENCE TO RELATED APPLICATIONS

This application claims the benefit of priorities to Chinese Application No. 202410982899.5, filed on Jul. 19, 2024, and U.S. Provisional Application No. 63/661,018, filed on Jun. 17, 2024, both of which are hereby incorporated by reference in their entireties.

### TECHNICAL FIELD

The present disclosure relates to the technical field of semiconductor chips, and in particular, to a semiconductor device, a manufacturing method thereof, a memory system and electronics.

### BACKGROUND

As the feature size of memory cells approaches the process lower limit, planar processes and manufacturing techniques become challenging and costly, which results in the storage density of 2D or planar NAND flash memory approaching the upper limit.

To overcome the limitations imposed by 2D or planar NAND flash memory, a memory with a three-dimensional structure (3D NAND) has been developed in the industry to increase storage density by disposing memory cells three-dimensionally over a substrate.

However, as the layers of 3D NAND are stacked, the length of the channel structure increases, and the current intensity in the channel structure decreases as the length of the channel structure increases.

### SUMMARY

According to one aspect of the present disclosure, a semiconductor device is provided. The semiconductor device may include a first stack structure, a source layer, and a second stack structure sequentially stacked along a first direction. The semiconductor device may include a first bit line and a second bit line. The first bit line may be located on a side of the first stack structure away from the second stack structure. The second bit line may be located on a side of the second stack structure away from the first stack structure. Both the first bit line and the second bit line may extend along a second direction. The second direction may intersect with the first direction. The semiconductor device may include a gate isolation structure that extends along a third direction and penetrates through the first stack structure, the source layer, and the second stack structure along the first direction. The third direction may intersect with a plane in which the first direction and the second direction are located. The gate isolation structure may include a first connection portion, a second connection portion, and a first isolation portion. The first connection portion may be disposed around the second connection portion in a plane parallel to the second direction and the third direction. The first isolation portion may be located between the first connection portion and the second connection portion. The first connection portion may be connected to the source layer. Two ends of the second connection portion along the first direction may be respectively connected to the first bit line and the second bit line.

In some implementations, the gate isolation structure may include a second isolation portion. In some implementations, the second connection portion may be disposed around the second isolation portion in a plane parallel to the second direction and the third direction.

In some implementations, the gate isolation structure may include a third isolation portion and a fourth isolation portion located on two opposite sides of the source layer. In some implementations, the third isolation portion may be located between the first connection portion and the first stack structure. In some implementations, the fourth isolation portion may be located between the first connection portion and the second stack structure.

In some implementations, the gate isolation structure may include a plurality of gate isolation structures. In some implementations, the plurality of gate isolation structures may be arranged in a plurality of columns along the second direction and arranged in a plurality of rows along the third direction, and two adjacent rows of the gate isolation structures may be staggered in the third direction.

In some implementations, the first bit line may include a plurality of first bit lines. In some implementations, the plurality of first bit lines may be sequentially arranged at intervals along the third direction. In some implementations, one first bit line may be connected to one end of one second connection portion. In some implementations, the first bit line may include the second bit line, which may include a plurality of second bit lines. In some implementations, the plurality of second bit lines may be sequentially arranged at intervals along the third direction. In some implementations, one second bit line is connected to the other end of the one second connection portion.

In some implementations, the semiconductor device may further include a dielectric structure. In some implementations, the dielectric structure may penetrate through the first stack structure, the source layer, and the second stack structure along the first direction. In some implementations, at least one dielectric structure may be between two adjacent gate isolation structures in the third direction.

In some implementations, in a plane parallel to the second direction and the third direction, a contour edge of a cross section of the dielectric structure may include at least one arc-shaped edge.

In some implementations, the semiconductor device may include a plurality of channel structures penetrating through the first stack structure, the source layer, and the second stack structure. In some implementations, the plurality of channel structures are arranged in a plurality of rows along the third direction, the plurality of channel structures are arranged in a plurality of columns along the second direction, and two adjacent rows of the channel structures are staggered in the third direction. In some implementations, a plurality of rows of the channel structures may be disposed between two adjacent rows of the gate isolation structures along the second direction. In some implementations, among the plurality of rows of the channel structures, one first bit line may be connected to at least one of the channel structures.

In some implementations, the channel structure may include a channel layer and a functional layer. In some implementations, the functional layer may be disposed around a portion of the channel layer. In some implementations, the channel layer may penetrate through the first stack structure, the source layer, and the second stack structure along the first direction and is in contact with the source layer. In some implementations, the functional layer may include a first portion and a second portion located on two opposite sides of the source layer. In some implementations, the first portion may penetrate through the first stack structure and may be in contact with the source layer. In some implementations, the second portion may penetrate through the second stack structure and may be in contact with the source layer.

In some implementations, the plurality of first bit lines constitute a plurality of first bit line groups, and the first bit line group includes at least two adjacent first bit lines. In some implementations, in the first direction, respective first bit lines in the first bit line group may overlap with respective gate isolation structures located in a same column.

In some implementations, one gate isolation structure in a column of the plurality of gate isolation structures overlapping the first bit line group may be connected to one first bit line in the first bit line group.

In some implementations, the plurality of gate isolation structures may have a same size in the third direction.

In some implementations, the semiconductor device may include a first contact. In some implementations, in the first direction, two ends of the first contact may be respectively connected to the first bit line and the second connection portion. In some implementations, the semiconductor device may include a second contact. In some implementations, in the first direction, two ends of the second contact may be respectively connected to the second bit line and the second connection portion.

In some implementations, the first stack structure may include first gate layers and first dielectric layers alternately stacked along the first direction. In some implementations, the second stack structure may include second gate layers and second dielectric layers alternately stacked along the first direction. In some implementations, the semiconductor device may further include a plurality of connection structures located on a side of the first stack structure and the second stack structure. In some implementations, one of the connection structures may be connected with at least one of the first gate layers. In some implementations, one of the connection structures may be connected with at least one of the second gate layers.

In some implementations, the first stack structure, the source layer, and the second stack structure together may constitute a repeating structure. In some implementations, the repeating structure may include a plurality of repeating structures, and the plurality of repeating structures are stacked along the first direction.

In some implementations, a peripheral circuit structure may be located on a side of the first bit line away from the first stack structure and being connected with the first bit line.

In some implementations, the semiconductor structure may include a third contact. In some implementations, in the first direction, two ends of the third contact may be respectively connected to the second bit line and the peripheral circuit structure. In some implementations, the semiconductor device may include a fourth contact. In some implementations, in the first direction, two ends of the fourth contact may be respectively connected to the first connection portion and the peripheral circuit structure.

According to another aspect of the present disclosure, a method of manufacturing a semiconductor device is provided. The method may include forming a first stack structure, a source layer, and a second stack structure sequentially stacked along a first direction. The method may include forming a gate isolation structure. The gate isolation structure may penetrate through the first stack structure, the source layer, and the second stack structure along the first direction. The gate isolation structure may include a first connection portion, a second connection portion, and a first isolation portion. The first connection portion may be disposed around the second connection portion. The first isolation portion may be located between the first connection portion and the second connection portion. The first connection portion may be connected to the source layer. The method may include forming a first bit line. The first bit line may be located on a side of the first stack structure away from the second stack structure. The first bit line may extend along a second direction. The gate isolation structure may extend along a third direction, the first bit line may be connected to one end of the second connection portion. The second direction may intersect with the first direction. The third direction may intersect a plane where the first direction and the second direction are located. The method may include forming a second bit line. In some implementations, the second bit line may be located on a side of the second stack structure away from the first stack structure, the second bit line may extend along the second direction, and the second bit line may be connected to the other end of the second connection portion.

In some implementations, the forming the first stack structure, the source layer, and the second stack structure sequentially stacked along the first direction may include forming a first deck structure. In some implementations, the first deck structure may include a plurality of first sacrificial layers and a plurality of first dielectric layers alternately stacked along a first direction. In some implementations, the forming the first stack structure, the source layer, and the second stack structure sequentially stacked along the first direction may include forming a second sacrificial layer. In some implementations, the second sacrificial layer and the first deck structure may be stacked along the first direction. In some implementations, the forming the first stack structure, the source layer, and the second stack structure sequentially stacked along the first direction may include forming a second deck structure. In some implementations, the second deck structure may be located on a side of the second sacrificial layer away from the first deck structure. In some implementations, the second deck structure may include a plurality of third sacrificial layers and a plurality of second dielectric layers alternately stacked along the first direction. In some implementations, the forming the first stack structure, the source layer, and the second stack structure sequentially stacked along the first direction may include forming a channel structure. In some implementations, the channel structure may penetrate through the first deck structure, the second sacrificial layer and the second deck structure. In some implementations, the forming the first stack structure, the source layer, and the second stack structure sequentially stacked along the first direction may include replacing the second sacrificial layer with a source layer. In some implementations, the source layer may be connected to the channel structure. In some implementations, the forming the first stack structure, the source layer, and the second stack structure sequentially stacked along the first direction may include replacing the first sacrificial layer with a first gate layer, and replacing the third sacrificial layer with a second gate layer.

In some implementations, after forming the first deck structure and before forming the second sacrificial layer, the method may further include removing a portion of the first deck structure to form a first channel hole and a first gate slit. In some implementations, both the first channel hole and the first gate slit may penetrate through the first deck structure, and the first gate slit is located on a side of the first channel hole along the second direction. In some implementations, after forming the second deck structure and before forming the channel structure, the method may further include removing a portion of the second deck structure and a portion of the second sacrificial layer to form a second channel hole and a second gate slit. In some implementations, the second channel hole may penetrate through the second deck structure to the first channel hole, the second channel hole and the first channel hole together constitute a channel hole, the second gate slit penetrates through the second deck structure to the first gate slit, and the second gate slit and the first gate slit together constitute a gate slit.

In some implementations, the forming the first deck structure may include forming a first sub-deck structure. In some implementations, the forming the first deck structure may include removing a portion of the first sub-deck structure to form a third channel hole and a third gate slit. In some implementations, the third channel hole and the third gate slit may both penetrate through the first sub-deck structure. In some implementations, the third gate slit may be located on a side of the third channel hole along the second direction. In some implementations, the forming the first deck structure may include forming a second sub-deck structure. In some implementations, the second sub-deck structure and the first sub-deck structure may be stacked along the first direction. In some implementations, the forming the second deck structure may include forming a third sub-deck structure. In some implementations, the forming the second deck structure may include removing a portion of the second sub-deck structure, a portion of the second sacrificial layer, and a portion of the third sub-deck structure to form a fourth channel hole and a fourth gate slit. In some implementations, the fourth channel hole may be connected with the third channel hole, and the fourth gate slit may be connected with the fourth channel hole. In some implementations, the forming the second deck structure may include forming a fourth sub-deck structure. In some implementations, the fourth sub-deck structure and the third sub-deck structure may be stacked along the first direction. In some implementations, the forming the second deck structure may include removing a portion of the fourth sub-deck structure to form a fifth channel hole and a fifth gate slit. In some implementations, the fifth channel hole may penetrate through the fourth sub-deck structure to the fourth channel hole. In some implementations, the third channel hole, the fourth channel hole and the fifth channel hole together may constitute a channel hole, the fifth gate slit may penetrates through the fourth sub-deck structure to the fourth gate slit, and the third gate slit, and the fourth gate slit and the fifth gate slit together may constitute a gate slit.

In some implementations, the forming the channel structure may include sequentially forming a functional layer and a channel layer in the channel hole. In some implementations, the functional layer may be disposed around a portion of the channel layer. In some implementations, the replacing the second sacrificial layer with the source layer may include removing a portion of the second sacrificial layer to form a filling space. In some implementations, the filling space may expose a portion of the functional layer. In some implementations, the replacing the second sacrificial layer with the source layer may include removing a portion of the functional layer through the filling space. In some implementations, the replacing the second sacrificial layer with the source layer may include forming the source layer in the filling space.

In some implementations, the forming the gate isolation structure may include sequentially forming a first connection portion, a first isolation portion, a second connection portion and a second isolation portion in the gate slit. In some implementations, the second connection portion may be disposed around the second isolation portion, the first connection portion may be disposed around the second connection portion, the first isolation portion may be located between the first connection portion and the second connection portion, and the first connection portion may be connected to the source layer.

In some implementations, after replacing the first sacrificial layer with the first gate layer and before forming the gate isolation structure, the method may include forming a third isolation portion and a fourth isolation portion in the gate slit. In some implementations, the third isolation portion may cover the first gate layer, and the fourth isolation portion may cover the second gate layer.

According to a further aspect of the present disclosure, a memory system is provided. The memory system may include a semiconductor device. The memory system may include a controller coupled to the semiconductor device to control the semiconductor device to store data. The semiconductor device may include a first stack structure, a source layer and a second stack structure sequentially stacked along a first direction. The semiconductor device may include a first bit line and a second bit line. The first bit line may be located on a side of the first stack structure away from the second stack structure. The second bit line may be located on a side of the second stack structure away from the first stack structure. Both the first bit line and the second bit line may extend along a second direction. The second direction may intersect with the first direction. The semiconductor device may include a gate isolation structure that extends along a third direction and penetrates through the first stack structure, the source layer, and the second stack structure along the first direction. The third direction may intersect with a plane where the first direction and the second direction are located. The gate isolation structure may include a first connection portion, a second connection portion, and a first isolation portion. The first connection portion may be disposed around the second connection portion in a plane parallel to the second direction and the third direction. The first isolation portion may be located between the first connection portion and the second connection portion. The first connection portion may be connected to the source layer. Two ends of the second connection portion along the first direction may be respectively connected to the first bit line and the second bit line.

According to yet another aspect of the present disclosure, an electronic device is provided. The electronic device may include a motherboard and a memory system disposed on the motherboard. The memory system may include a semiconductor device. The memory system may include a controller coupled to the semiconductor device to control the semiconductor device to store data. The semiconductor device may include a first stack structure, a source layer, and a second stack structure sequentially stacked along a first direction. The semiconductor device may include a first bit line and a second bit line. The first bit line may be located on a side of the first stack structure away from the second stack structure. The second bit line may be located on a side of the second stack structure away from the first stack structure. Both the first bit line and the second bit line may extend along a second direction, and the second direction intersects with the first direction. The semiconductor device may include a gate isolation structure that extends along a third direction and penetrates through the first stack structure. The source layer and the second stack structure along the first direction. The third direction may intersect with a plane where the first direction and the second direction are located. The gate isolation structure may include a first connection portion, a second connection portion and a first isolation portion. The first connection portion may be disposed around the second connection portion in a plane parallel to the second direction and the third direction. The first isolation portion may be located between the first connection portion and the second connection portion. The first connection portion may be connected to the source layer. Two ends of the second connection portion along the first direction may be respectively connected to the first bit line and the second bit line.

### BRIEF DESCRIPTION OF THE DRAWINGS

In order to more clearly illustrate the technical solutions in the present disclosure, the accompanying drawings required to be used in some implementations of the present disclosure will be briefly described below, and obviously, the accompanying drawings described below are only the accompanying drawings of some implementations of the present disclosure, and for those skilled in the art, other accompanying drawings may also be obtained from these accompanying drawings. In addition, the drawings in the following description may be regarded as schematic diagrams, and are not intended to limit actual sizes of products, actual processes of methods, and the like involved in the implementations of the present disclosure.

FIG. 1 is a schematic diagram of a three-dimensional structure of a three-dimensional memory according to some implementations;

FIG. 2 is a cross-sectional view of a three-dimensional memory according to some implementations;

FIG. 3 is a cross-sectional view of a memory cell string in the three-dimensional memory shown in FIG. 1 along a section line A-A′;

FIG. 4 is an equivalent circuit diagram of the memory cell string in FIG. 3;

FIG. 5 is a structural schematic diagram of a semiconductor device according to some implementations;

FIG. 6 is a structural schematic diagram of a gate isolation structure in a Y-Z plane according to some implementations;

FIG. 7 is a structural schematic diagram of a semiconductor device in a Y-Z plane according to some implementations;

FIG. 8 is a cross-sectional view along A-A in FIG. 7;

FIG. 9 is a structural schematic diagram of a dielectric structure in a Y-Z plane according to some implementations;

FIG. 10 is a structural schematic diagram of a semiconductor device according to some other implementations;

FIG. 11 is a spliced view of two sections along B-B and C-C in FIG. 10;

FIG. 12 is a structural schematic diagram of a plurality of repeating structures according to some implementations;

FIG. 13 is a flow chart of a method of manufacturing a semiconductor device according to some implementations;

FIGS. 14-19 are structural schematic diagrams of a semiconductor device during manufacture, according to some implementations;

FIG. 20 is a block diagram of a memory system according to some implementations;

FIG. 21 is a block diagram of a memory system according to some other implementations;

FIG. 22 is a block diagram of an electronics according to some implementations.

### REFERENCE NUMERALS

10, three-dimensional memory; 100, peripheral device; 110, base board; 120, transistor; 130, peripheral interconnection layer; 200, semiconductor structure; 290, array interconnection layer; 400, memory cell string; 500, bonding interface; SL, source layer; 410, channel structure; 4101, first end; 4102, second end; 411, channel layer; 412, functional layer; 4121, tunneling layer; 4122, storage layer; 4123, blocking layer; 4124, first portion; 4125, second portion; 300, semiconductor layer; 600, semiconductor device; 610; first stack structure; 611, first gate layer; 612, first dielectric layer; 6101, first sub-stack structure; 6102, second sub-stack structure; 620, second stack structure; 621, second gate layer; 622, second dielectric layer; 6201, third sub-stack structure; 6202, fourth sub-stack structure; 630, gate isolation structure; 631, first connection portion; 632, second connection portion; 633, first isolation portion; 634, second isolation portion; 635, third isolation portion; 636, fourth isolation portion; 640, dielectric structure; 641, arc-shaped edge; 650, connection structure; 651, connection pillar; 652: first connection layer; 653, second connection layer; 654, third isolation layer; 655, fourth isolation layer; 656, fifth isolation layer; 670, third stack structure; 671, third dielectric layer; 672, fourth dielectric layer; 680, fourth stack structure; 681, fifth dielectric layer; 682, sixth dielectric layer; 101, first region; 102, second region; 103, memory block; 690, repeating structure; 660, peripheral circuit structure; BL-1, first bit line; BL-2, second bit line; 700, first bit line group; 701, first contact; 702, second contact; 703, third contact; 704, fourth contact; 710, first deck structure; 7101, first sub-deck structure; 7102, second sub-deck structure; 711, first sacrificial layer; 720, second deck structure; 7201, third sub-deck structure; 7202, fourth sub-deck structure; 721, third sacrificial layer; 730, second sacrificial layer; 731, first filling space; 740, structural pile; 750, channel hole; 751, first channel hole; 752, second channel hole; 753, third channel hole; 754, fourth channel hole; 755, fifth channel hole; 760, gate slit; 761, first gate slit; 762, second gate slit; 763, third gate slit; 764, fourth gate slit; 765, fifth gate slit.

### DETAILED DESCRIPTION

The technical solutions in some implementations of the present disclosure will be clearly and completely described below with reference to the accompanying drawings, and obviously, the described implementations are only some but not all implementations of the present disclosure. All other implementations obtained by those skilled in the art based on the implementations provided by the present disclosure fall within the protection scope of the present disclosure.

In the description of the present disclosure, it should be construed that the orientation or position relationship indicated by the terms “center”, “upper”, “lower”, “front”, “rear”, “left”, “right”, “vertical”, “horizontal”, “top”, “bottom”, “inner”, “outer” and the like is based on the orientation or position relationship shown in the accompanying drawings, and is only for the convenience of describing the present disclosure and simplifying the description, rather than indicating or implying that the indicated device or element must have a specific orientation, be constructed and operated in a specific orientation, and therefore cannot be construed as a limitation to the present disclosure.

Unless required otherwise by the context, throughout the specification and claims, the term “including” is to be construed as open, inclusive, i.e., “including, but not limited to”. In the description of the specification, the terms “one implementation”, “some implementations”, “example implementations”, “exemplarily” or “some examples” and the like are intended to indicate that a particular feature, structure, material or characteristic related to the implementation or example is included in at least one implementation or example of the present disclosure. The schematic representations of the above terms do not necessarily refer to the same implementation or example. Further, the particular feature, structure, material, or characteristic described may be included in any suitable manner in any one or more implementations or examples.

Hereinafter, the terms “first” and “second” are used for descriptive purposes only, and cannot be construed as indicating or implying relative importance or implicitly indicating the number of technical features indicated. Thus, features defined with “first” and “second” may explicitly or implicitly include one or more such features. In the description of the implementations of the present disclosure, unless otherwise indicated, “a plurality of” means two or more.

In describing some implementations, “coupled” and “connected” and derivatives thereof may be used. For example, the term “connected” may be used in describing some implementations to indicate that two or more components are in direct physical or electrical contact with each other. As another example, the term “coupled” may be used in describing some implementations to indicate that two or more components are in direct physical or electrical contact. However, the term “coupled” may also mean that two or more components are not in direct contact with each other, but still cooperate or interact with each other. The implementations disclosed herein are not necessarily limited to the content herein.

“At least one of A, B, and C” has the same meaning as “at least one of A, B, or C”, each includes the following combinations of A, B, and C: A only, B only, C only, a combination of A and B, a combination of A and C, a combination of B and C, and a combination of A, B, and C.

“At least one of A or B” includes three combinations: A only, B only, and a combination of A and B.

The use of “adapted to” or “configured to” herein means open and inclusive language that does not exclude a device adapted to or configured to perform additional tasks or operations.

Additionally, the use of “based on” means open and inclusive, as a process, operation, calculation, or other action “based on” one or more of the stated conditions or values may in practice be based on additional conditions or beyond the stated values.

As used herein, “about”, “roughly”, or “approximately” includes the values set forth as well as an average value within an acceptable deviation range for a particular value, where the acceptable deviation range is determined by one of ordinary skill in the art in view of the measurements being discussed and errors associated with a particular amount of measurements (i.e., limitations of the measurement system).

In the context of the present disclosure, the meanings of “on,” “over,” and “above” should be interpreted in a broadest manner such that “on” has not only the meaning of “directly on” something but also the meaning of “on” with intermediate features or layers therebetween, and “over” or “above” has not only the meaning of “over” or “above” some something but also the meaning of “over” or “above” without intermediate features or layers therebetween (i.e., directly on something).

Example implementations are described herein with reference to at least one of cross-sectional or plan views as idealized example drawings. In the drawings, the thicknesses of the layers and regions are enlarged for clarity. Accordingly, variations in shape relative to the drawings due to, for example, at least one of manufacturing technique or tolerance are contemplated. Thus, the example implementations should not be construed as limited to the shapes of the regions illustrated herein, but include shape deviations due to, for example, manufacturing. For example, an etched area shown as a rectangle will typically have curved features. Thus, the regions shown in the figures are schematic in nature, and their shapes are not intended to illustrate the actual shapes of the regions of the device, and are not intended to limit the scope of the example implementations.

As used herein, the term “substrate” refers to a material on which a subsequent layer of material may be added. The substrate itself may be patterned. The material added on the substrate may be patterned or may remain unpatterned. Further, the substrate may include a variety of semiconductor materials such as silicon, germanium, gallium arsenide, indium phosphide, or the like. Alternatively, the substrate may be made of a non-conductive material such as glass, plastic, or sapphire wafer.

As used herein, “parallel”, “perpendicular”, “equal” include the illustrated situation as well as situations that are similar to the illustrated situation within an acceptable deviation range, where the acceptable deviation range is determined by one of ordinary skill in the art in view of the measurements being discussed and errors associated with a particular quantity of measurements (i.e., limitations of the measurement system). For example, “parallel” includes absolutely parallel and approximately parallel, where the acceptable deviation range of approximately parallel may be, for example, a deviation within 5°; and “perpendicular” includes absolutely perpendicular and approximately perpendicular, where the acceptable deviation range of approximately perpendicular may also be, for example, a deviation within 5°. “Equal” includes absolutely equal and approximately equal, where the acceptable deviation range of approximately equal, for example, means the difference between equivalent two may be less than or equal to 5% of either of the two.

The term “three-dimensional memory” refers to a semiconductor device formed by memory cell transistor strings (referred to herein as “memory cell strings”, such as NAND memory cell strings) disposed in an array on a main surface of a substrate or a source layer and extending along a direction perpendicular to the substrate or the source layer. As used herein, the term “vertical/vertically” means nominally perpendicular to the main surface (i.e., lateral surface) of the substrate or source layer.

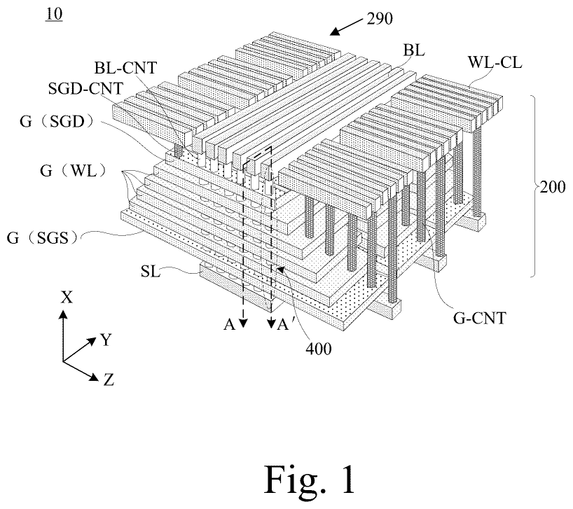

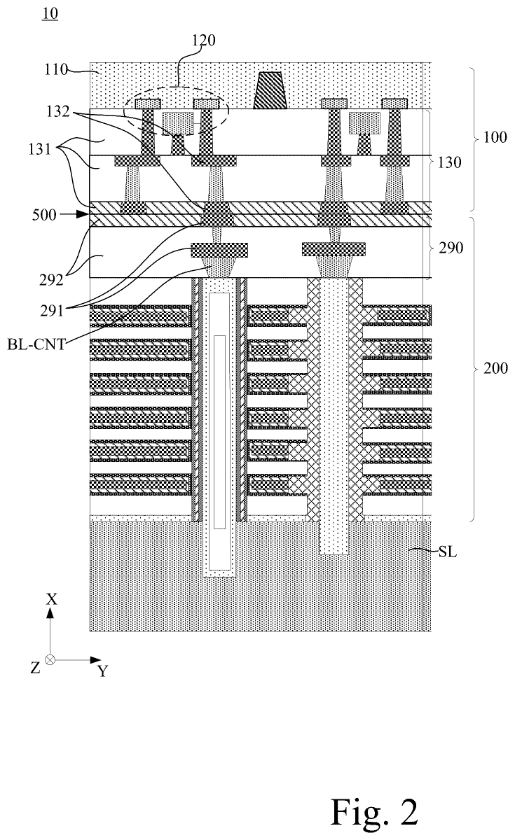

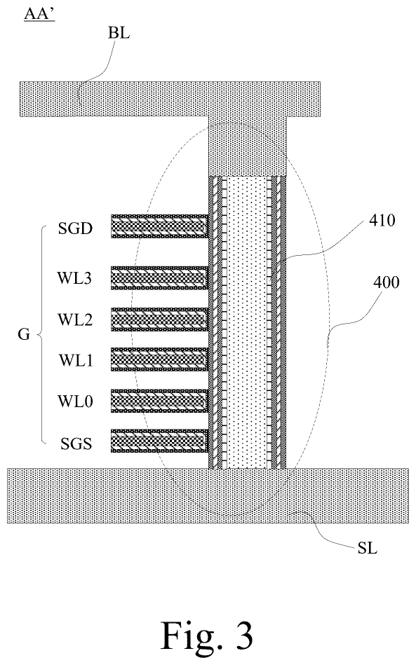

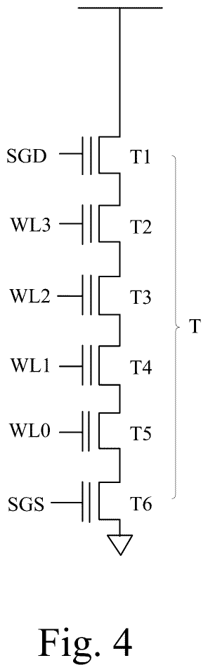

FIG. 1 is a schematic diagram of a three-dimensional structure of a three-dimensional memory according to some implementations. FIG. 2 is a cross-sectional view of a three-dimensional memory according to some implementations. FIG. 3 is a cross-sectional view of a memory cell string in the three-dimensional memory shown in FIG. 1 along a cross-sectional line A-A′. FIG. 4 is an equivalent circuit diagram of the memory cell string in FIG. 3.

Referring to FIG. 1 and FIG. 2, a three-dimensional memory 10 provided by some implementations of the present disclosure is in an X-Y-Z three-dimensional coordinate system, the three-dimensional memory 10 extends in a Y-Z plane, a second direction Y is, for example, an extending direction of a bit line BL, and a third direction Z is, for example, an extending direction of a word line WL. A first direction X is perpendicular to the Y-Z plane.

It should be noted that the first direction X intersects the second direction Y, and the third direction Z intersects the X-Y plane. The present disclosure only takes the example of the first direction X, the second direction Y, and the third direction Z being perpendicular to each other as an example, to explain and illustrate the structures provided in some implementations of the present disclosure.

Referring to FIGS. 1 and 2, some implementations of the present disclosure provide a three-dimensional memory 10. The three-dimensional memory 10 may include a semiconductor structure 200. The 3D memory 10 may further include a source layer SL coupled to the semiconductor structure 200, and a peripheral device 100 coupled to the semiconductor structure 200. The peripheral device 100 may be disposed on a side of the semiconductor structure 200 away from the source layer SL.

The source layer SL may include a semiconductor material such as monocrystalline silicon, monocrystalline germanium, a group III-V compound semiconductor material, a group II-VI compound semiconductor material, and other suitable semiconductor materials. The source layer SL may be partially or fully doped. In some examples, the source layer SL may include a doped region which is doped with a p-type dopant. The source layer SL may further include an undoped region.

The semiconductor structure 200 may include memory cell transistor strings (referred to herein as “memory cell strings”, e.g., NAND memory cell strings) disposed in an array. The source layer SL may be coupled to source ends of a plurality of memory cell strings 400.

For example, referring to FIG. 3 and FIG. 4, a memory cell string 400 may include a plurality of transistors T, a transistor T (for example, T2 to T5 in FIG. 4) may be set as a memory cell, and these transistors T are connected together to form the memory cell string 400. A transistor T (e.g., each transistor T) may be formed by a channel structure 410 and a gate line G surrounding the channel structure 410. The gate line G is configured to control a conducting state of the transistor.

It should be noted that the number of the transistors T in FIG. 1 to FIG. 4 is merely illustrative, and the memory cell string 400 of the three-dimensional memory 10 provided by the implementations of the present disclosure may further include other numbers of transistors, such as 4, 16, 32, and 64.

Further, along the first direction X, a lowermost gate line among a plurality of gate lines G (for example, the gate line among the plurality of gate lines G which is closest to the source layer SL) is configured as a source terminal selection gate SGS, and the source terminal selection gate SGS is configured to control the conducting state of the transistor T6, thereby controlling a conducting state of the source channel in the memory cell string 400. Along the first direction X, an uppermost gate line among the plurality of gate lines G (for example, a gate line among the plurality of gate lines G which is farthest from the source layer SL) is configured as a drain terminal select gate SGD, and the drain terminal select gate SGD is configured to control the conducting state of the transistor T1, thereby controlling a conducting state of the drain channel in the memory cell string 400. Middle gate lines among the plurality of gate lines G may be configured as a plurality of word lines WL, for example, including a word line WL0, a word line WL1, a word line WL2, and a word line WL3. By writing different voltages on the word lines WLs, data writing, reading, and erasing of respective memory cells (e.g., transistors T) in the memory cell string 400 may be completed.

With continued reference to FIGS. 1 and 2, in some implementations, the semiconductor structure 200 may further include an array interconnection layer 290. The array interconnect layer 290 may be coupled with the memory cell strings 400. The array interconnection layer 290 may include drain terminals (e.g., bit lines BL) of the memory cell strings 400, and the drain terminals may be coupled to semiconductor channels of respective transistors T in at least one memory cell string 400.

The array interconnection layer 290 may include one or more first interlayer insulating layers 292, and the array interconnection layer 290 may further include a plurality of contacts insulated from each other by the first interlayer insulating layers 292. The contacts include, for example, a bit line contact BL-CNT, a drain terminal select gate contact SGD-CNT, and a gate line contact G-CNT. The bit line contact BL-CNT is coupled to the bit line BL, the drain terminal select gate contact SGD-CNT is coupled to the drain terminal select gate SGD, and the gate line contact G-CNT is coupled to the gate line G.

The array interconnect layer 290 may also include one or more first interconnect conductor layers 291. The first interconnection conductor layer 291 may include a plurality of connection lines, such as a bit line BL, and a word line connection line WL-CL coupled to the word line WL. The material of the first interconnection conductor layer 291 and the contacts may be a conductive material, for example, one or more of tungsten, cobalt, copper, aluminum, and metal silicide, as well as other conductive materials. The material of the first interlayer insulating layer 292 is an insulating material, the insulating material may be, for example, one or more of silicon oxide, silicon nitride, and high dielectric constant insulating materials, or may be other insulating materials.

The peripheral device 100 may include a peripheral circuit. The peripheral circuit is configured to control and sense the array device. The peripheral circuit may be any suitable digital, analog, or mixed signal control and sensing circuit for supporting array device operation (or task), including but not limited to page buffers, decoders (e.g., row decoders and column decoders), read amplifiers, drivers (e.g., word line drivers), charge pumps, current or voltage references, or any active or passive components of the circuit (e.g., transistors, diodes, resistors, or capacitors). The peripheral circuits may also include any other circuits compatible with advanced logic processes, including logic circuits (such as processors and programmable logic devices (PLDs)) or memory circuits (such as static random-access memories (SRAMs)).

For example, in some implementations, the peripheral device 100 may include a base board 110, a transistor 120 disposed on the base board 110, and a peripheral interconnect layer 130 disposed on the base board 110. The peripheral circuit may include a transistor 120.

The base board 110 may be made of monocrystalline silicon or other suitable materials, such as silicon germanium, germanium, or a silicon-on-insulator film.

The peripheral interconnect layer 130 is coupled to the transistor 120 to achieve the transmission of electrical signals between the transistor 120 and the peripheral interconnect layer 130. The peripheral interconnection layer 130 may include one or more second interlayer insulating layers 131, and the peripheral interconnection layer 130 may further include one or more second interconnection conductor layers 132. Different second interconnection conductor layers 132 may be coupled by contacts. The materials of the second interconnection conductor layer 132 and the contacts may include a conductive material, for example, one or more of tungsten, cobalt, copper, aluminum, and metal silicide, as well as other suitable materials. The material of the second interlayer insulating layer 131 includes an insulating material, for example, one or more of silicon oxide, silicon nitride, and high dielectric constant insulating materials, as well as other suitable materials.

Peripheral interconnect layer 130 may be coupled with the array interconnect layer 290 such that the semiconductor structure 200 and the peripheral device 100 may be coupled. For example, since the peripheral interconnection layer 130 is coupled to the array interconnection layer 290, the peripheral circuit in the peripheral device 100 may be coupled to the memory cell strings in the semiconductor structure 200, to achieve the transmission of electrical signals between the peripheral circuit and the memory cell strings. In some possible implementations, a bonding interface 500 may be disposed between the peripheral interconnection layer 130 and the array interconnection layer 290, and the peripheral interconnection layer 130 and the array interconnection layer 290 may be bonded and coupled to each other through the bonding interface 500.

Referring to FIG. 1 and FIG. 3, the source layer SL is located on a side of the semiconductor structure 200, for example, the source layer SL is located in a lowest plane in the first direction X, one end of the channel structure 410 is connected to the source layer SL, and the source layer SL applies a voltage to the channel structure 410, so that a voltage difference is generated between two ends of the channel structure 410, to drive the channel structure 410 to generate a current. However, as the users pursue large capacity and small volume three-dimensional memory, the 3D NAND increases the storage capacity of the three-dimensional memory 10 by increasing the length of the channel structure 410 in the first direction X. As the length of the channel structure 410 in the first direction X increases, the resistance of the channel structure 410 increases and the voltage difference of the channel structure 410 decreases, thus the current intensity in the channel structure 410 decreases, and it is difficult to meet the device performance such as a storage speed and a response speed of the three-dimensional memory 10.

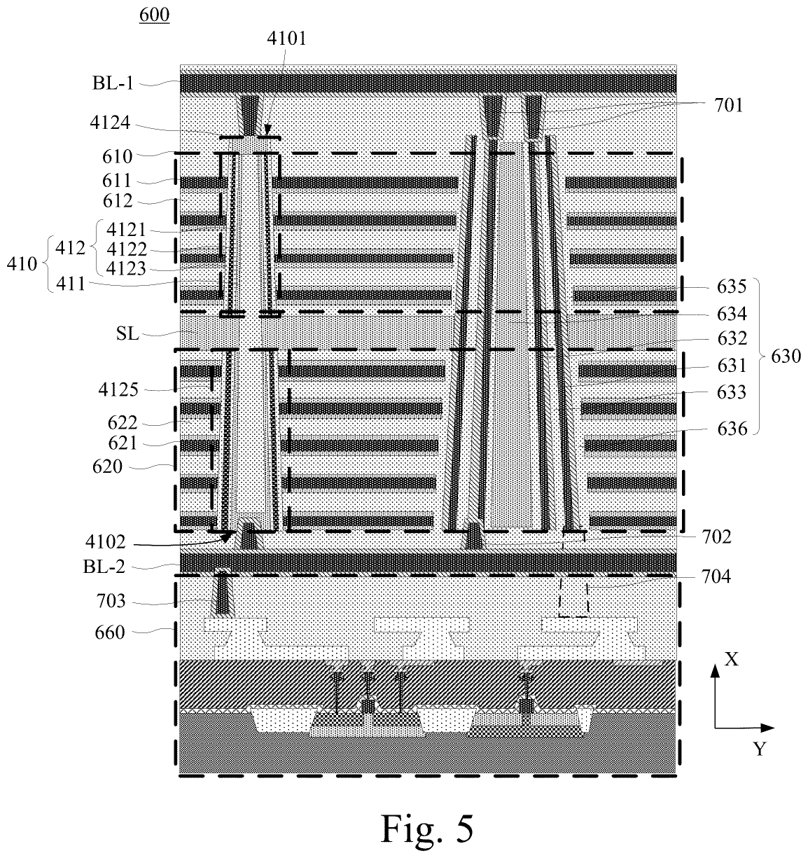

Based on this, some implementations of the present disclosure provide a semiconductor device. FIG. 5 is a structural schematic diagram of a semiconductor device according to some implementations. Referring to FIG. 5, a semiconductor device 600 provided by the present disclosure includes: a first stack structure 610, a source layer SL and a second stack structure 620 sequentially stacked along a first direction X.

In some examples, the first stack structure 610 may include a plurality of first gate layers 611 and a plurality of first dielectric layers 612 alternately stacked along the first direction X. For example, the first gate layers 611 and the first dielectric layers 612 alternately disposed along the first direction X are stacked to form a plurality of first gate layers 611 and a plurality of first dielectric layers 612 spaced apart from each other. It may also be construed that one first gate layer 611 and one first dielectric layer 612 together constitute one first gate structure pair, and the first stack structure 610 includes a plurality of first gate structure pairs stacked along the first direction X.

In some examples, the number of layers of the first gate layers 611 may be 4, 16, 32, 64, 128, 256, or the like. The number of layers of the first dielectric layers 612 may be 4, 16, 32, 64, 128, 256, or the like. The thickness of the first gate layer 611 (e.g., a size along the first direction X) may be substantially equal to the thickness of the first dielectric layer 612 or may be different from the thickness of the first dielectric layer 612. For example, the thickness of the first dielectric layer 612 is greater than the thickness of the first gate layer 611.

In some examples, the first gate layer 611 may include a conductive material, the conductive material includes, but is not limited to, one or more of tungsten (W), cobalt (Co), copper (Cu), aluminum (Al), polysilicon, doped silicon, and silicide, or may be other suitable conductive materials. In some examples, the first gate layer 611 includes a metal layer, such as a tungsten layer. In some examples, the first gate layer 611 includes a doped polysilicon layer. The polysilicon may be doped to a desired doping concentration with a suitable dopant so that the polysilicon may become a conductive material for the first gate layer 611.

In some examples, the first dielectric layer 612 may include an insulating material, and the insulating material may include one or more of silicon oxide, silicon nitride, silicon oxynitride, and high dielectric constant insulating materials, or may be other suitable insulating materials. The dielectric constant of silicon oxynitride is higher than that of silicon oxide, for example, in an environment of about 20° C., the dielectric constant of silicon oxynitride may be 4-7. In some examples, the first dielectric layer 612 includes a silicon oxide layer. In some examples, the first dielectric layer 612 includes a silicon oxynitride layer.

In some examples, the thickness of the first gate layer 611 (e.g., a size along the first direction X) may be between 10 nm and 50 nm, for example, the thickness of the first gate layer 611 may be 10 nm, 15 nm, 18.3 nm, 20 nm, 25 nm, 27.7 nm, 30 nm, 35 nm, 40 nm, 45 nm, 50 nm, etc. Similarly, the thickness of the first dielectric layer 612 (e.g., a size along the first direction X) may be between 10 nm and 50 nm, for example, the thickness of the first dielectric layer 612 may be 10 nm, 15 nm, 18.3 nm, 20 nm, 25 nm, 27.7 nm, 30 nm, 35 nm, 40 nm, 45 nm, 50 nm, or the like. The first gate layer 611 may be a gate line G (see FIG. 3) surrounding the memory cell string, and may extend laterally (e.g., along the third direction Z) as a word line WL (see FIG. 1).

In this implementation, the second stack structure 620 may include a plurality of second gate layers 621 and a plurality of second dielectric layers 622 alternately stacked along the first direction X, for example, the second gate layers 621 and the second dielectric layers 622 alternately disposed along the first direction X are stacked to form a plurality of second gate layers 621 and a plurality of second dielectric layers 622 spaced apart from each other. It may also be construed that one second gate layer 621 and one second dielectric layer 622 together constitute one second gate structure pair, and the second stack structure 620 includes a plurality of second gate structure pairs stacked along the first direction X.

It may be construed that the component material, thickness, and number of the second gate layers 621 may refer to the foregoing examples of those of the first gate layers 611. The component material, thickness, and number of the second dielectric layers 622 may refer to the foregoing examples of those of the first dielectric layers 612. However, the component material, thickness and number of the second gate layers 621 may be the same as or different from those of the first gate layers 611, and the component material, thickness and number of the second dielectric layers 622 may be the same as or different from those of the first dielectric layers 612.

It should be noted that the number of stacked layers of the first stack structure 610 and the second stack structure 620 may be the same or different. For example, the first stack structure 610 may be composed of a plurality of stack structures, and the second stack structure 620 may also be composed of a plurality of stack structures, which is not limited in the present disclosure.

In this implementation, the semiconductor device 600 further includes a plurality of channel structures 410. The channel structure 410 may penetrate through the first stack structure 610, the source layer SL, and the second stack structure 620 along the first direction X, and the channel structure 410 is connected to the source layer SL.

The channel structure 410 has a first end 4101 and a second end 4102 disposed along the first direction X. The source layer SL is disposed between the first stack structure 610 and the second stack structure 620, and the channel structure 410 penetrates through the first stack structure 610, the source layer SL, and the second stack structure 620 along the first direction X, thus the connection between the source layer SL and the channel structure 410 may be located between the first end 4101 and the second end 4102. In this way, the source layer SL applies a voltage to the channel structure 410, so that a voltage difference can be generated between the connection between the source layer SL and the channel structure 410 and both the first end 4101 and the second end 4102, to drive the channel structure 410 to generate a current.

Compared with a three-dimensional memory in which the source layer SL is connected to the first end 4101 or the second end 4102, the semiconductor device 600 in this implementation shortens the length, in the first direction X, of the channel structure 410 to be driven by the source layer SL, which can improve the problem that the resistance of the channel structure 410 increases and the voltage difference decreases due to the increase of the length of the channel structure 410, and is beneficial to increasing the current intensity in the channel structure 410, thereby improving the device performance such as the storage speed and the response speed of the semiconductor device 600.

This solution has strong ductility and can continue to increase the number of stacked layers of the first stack structure 610 or the second stack structure 620, thereby increasing the length of the channel structure 410 in the first direction X and increasing the storage capacity of the channel structure 410. The source layer SL is located between the first stack structure 610 and the second stack structure 620, which improves the problem of weak current intensity in the channel structure 410 due to increasing the length of the channel structure 410 while increasing the storage capacity of the channel structure 410.

It should be noted that “the first stack structure 610, the source layer SL, and the second stack structure 620 sequentially stacked along the first direction X” may be construed that the source layer SL is disposed in one dielectric layer of one stack structure, and the source layer SL separates the stack structure into the first stack structure 610 and the second stack structure 620 (as shown in FIG. 5). Alternatively, it may also be construed as that the source layer SL is disposed between the first stack structure 610 and the second stack structure 620. Moreover, the source layer SL is connected to the channel structure 410, and the source layer SL can drive the channel structure 410 upward and downward simultaneously, thereby shortening the length of the channel structure 410 to be driven by the source layer SL, increasing the current intensity in the channel structure 410, and further improving the device performance such as the storage speed and the response speed of the semiconductor device 600.

In addition, the semiconductor device 600 further includes a first bit line BL-1 and a second bit line BL-2. The first bit line BL-1 is located on a side of the first stack structure 610 away from the second stack structure 620, the second bit line BL-2 is located on a side of the second stack structure 620 away from the first stack structure 610, and both the first bit line BL-1 and the second bit line BL-2 extend along the second direction Y. Two ends of the channel structure 410 along the first direction X are respectively connected to the first bit line BL-1 and the second bit line BL-2. The semiconductor device 600 further needs to connect the first bit line BL-1 and the second bit line BL-2 respectively through two circuits, so more metal lines are required, resulting in higher cost.

Based on this, the first bit line BL-1 may be electrically connected to the second bit line BL-2, and the first bit line BL-1 and the second bit line BL-2 may share one circuit, thereby reducing metal lines which is advantageous for reducing the cost. In some examples, by disposing a conductive structure which penetrates through the first stack structure 610, the source layer SL and the second stack structure 620 so that its two ends along the first direction X are respectively connected to the first bit line BL-1 and the second bit line BL-2, the first bit line BL-1 and the second bit line BL-2 may be electrically connected. However, adding the conductive structure may increase the size of the semiconductor device 600 in the second direction Y.

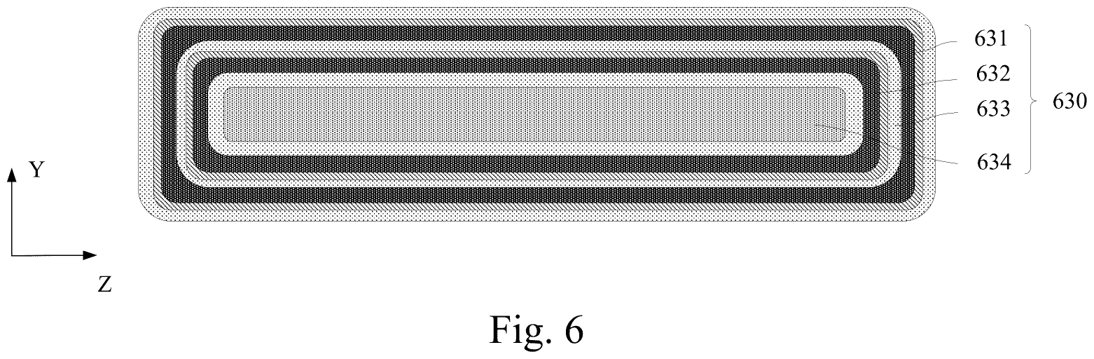

Based on this, referring to FIG. 5 and FIG. 6, the semiconductor device 600 provided in this implementation further includes a gate isolation structure 630. The gate isolation structure 630 extends along the third direction Z and penetrates through the first stack structure 610, the source layer SL and the second stack structure 620 along the first direction Y. The gate isolation structure 630 includes a first connection portion 631, a second connection portion 632, and a first isolation portion 633. In a plane parallel to the second direction Y and the third direction Z, the first connection portion 631 is disposed around the second connection portion 632, the first isolation portion 633 is located between the first connection portion 631 and the second connection portion 632, the first connection portion 631 is connected to the source layer SL, and two ends of the second connection portion 632 along the first direction X are respectively connected to the first bit line BL-1 and the second bit line BL-2.

In some examples, referring to FIG. 6, in a plane parallel to the second direction Y and the third direction Z, the second connection portion 632 may be of an annular structure, the first isolation portion 633 may also be of an annular structure, the first isolation portion 633 may be disposed around the second connection portion 632, and the first isolation portion 633 may be in contact with the second connection portion 632. The first connection portion 631 may also be of an annular structure, the first connection portion 631 may be disposed around the first isolation portion 633, and the first connection portion 631 may be in contact with the first isolation portion 633.

It should be noted that the first isolation portion 633 is located between the first connection portion 631 and the second connection portion 632, and it may be construed that the first isolation portion 633 covers all the peripheral surface of the second connection portion 632, so that the first connection portion 631 is isolated from the second connection portion 632; or it may be further construed that the first connection portion 631 is disposed around the second connection portion 632, and the first isolation portion 633 fills a gap between the first connection portion 631 and the second connection portion 632, so that the first connection portion 631 is isolated from the second connection portion 632.

In addition, the second connection portion 632 has conductivity, and the second connection portion 632 penetrates through the first stack structure 610, the source layer SL and the second stack structure 620. If the second connection portion 632 is connected to the first gate layer 611 or the second gate layer 621, the semiconductor device 600 cannot work normally. Therefore, by disposing the first isolation portion 633 to cover the surface of the second connection portion 632, it is beneficial to prevent the second connection portion 632 from being connected to the first gate layer 611 or the second gate layer 621, and it is beneficial to improve the storage stability of the semiconductor device 600.

It should be further noted that the first connection portion 631 is configured to connect the source layer SL and an external circuit, and therefore, the first connection portion 631 may penetrate through the first stack structure 610 and the source layer SL, or the first connection portion 631 may penetrate through the second stack structure 620 and the source layer SL, or the first connection portion 631 may penetrate through the first stack structure 610, the source layer SL, and the second stack structure 620. The implementation of the present disclosure is illustrated by taking the first connection portion 631 penetrating through the first stack structure 610, the source layer SL and the second stack structure 620 as an example.

In some examples, the component material of the first connection portion 631 and the second connection portion 632 may include a conductive material. The conductive material includes, but is not limited to, one or more of tungsten (W), cobalt (Co), copper (Cu), aluminum (Al), polysilicon, doped silicon, and silicide, or may be other suitable conductive materials. When the component material of the first connection portion 631 or the second connection portion 632 includes metal, the component material of the first connection portion 631 or the second connection portion 632 may further include titanium nitride. Disposing a layer of titanium nitride on the surface of the metal material is beneficial to prevent diffusion of the metal material, and is beneficial to improve the structural stability of the gate isolation structure 630 as the titanium nitride has good adhesion.

In some examples, the component material of the first isolation portion 633 may include an insulating material. The insulating material may include one or more of silicon oxide, silicon nitride, silicon oxynitride, and high dielectric constant insulating materials, or may be other suitable insulating materials.

Through the above arrangement, the first bit line BL-1 and the second bit line BL-2 may be electrically connected through the second connection portion 632, and the gate isolation structure 630 is a structure originally existing in the semiconductor device 600, and no additional conductive structure is needed, which is beneficial to control the size of the semiconductor device 600 in the second direction Y to be no longer increased, and is beneficial for the miniaturization development of the semiconductor device 600. In addition, the first bit line BL-1 and the second bit line BL-2 are electrically connected through the gate isolation structure 630, which is beneficial to simplify the circuit design of the semiconductor device 600, reducing metal lines and reducing the manufacturing cost of the semiconductor device 600.

However, disposing the source layer SL between the first stack structure 610 and the second stack structure 620 requires that an conductive structure penetrating through the first stack structure 610 or the second stack structure 620 to be additionally disposed for connecting the source layer SL and an external circuit, and the external circuit communicates electrical signals to and from the source layer SL to control the channel structure 410 to read or write information. This arrangement can increase the size of the semiconductor device 600 in the second direction Y.

In this implementation, the source layer SL is connected to the first connection portion 631, the external circuit may communicate electrical signals to and from the source layer SL through the first connection portion 631, and the gate isolation structure 630 is a structure originally existing in the semiconductor device 600 without additionally adding a new conductive structure, hence the size of the semiconductor device 600 in the second direction Y will not be increased, which is beneficial for the miniaturization development of the semiconductor device 600. In addition, the first connection portion 631 is of an annular structure, and the portion of the first connection portion 631 penetrating through the source layer SL is all connected to the source layer SL, which is beneficial to increase the contact area between the first connection portion 631 and the source layer SL and to reduce the resistance between the first connection portion 631 and the source layer SL, thus increasing the current intensity between the first connection portion 631 and the source layer SL and improving device performance such as the storage speed and the response speed of the semiconductor device 600.

The source layer SL is led out through the gate isolation structure 630, and the first bit line BL-1 and the second bit line BL-2 are connected, so that the structural design of the semiconductor device 600 can be simplified, which is beneficial for reducing the size of the semiconductor device 600 in the second direction Y and improving the storage density of the semiconductor device 600.

In some implementations, referring to FIGS. 5 and 6, the gate isolation structure 630 further includes a second isolation portion 634. In a plane parallel to the second direction Y and the third direction Z, the second connection portion 632 is disposed around the second isolation portion 634.

In some examples, the component material of the second isolation portion 634 may include an insulating material. The insulating material may include one or more of more of silicon oxide, silicon nitride, silicon oxynitride, and high dielectric constant insulating materials, or may be other suitable insulating materials.

The second isolation portion 634 may be a pillar structure penetrating through the first stack structure 610, the source layer SL, and the second stack structure 620 along the first direction X. By disposing the second connection portion 632 around the second isolation portion 634, and the second isolation portion 634 may provide a supporting force for the second connection portion 632. It may be construed that the second connection portion 632 may be of an annular structure, and the second isolation portion 634 fills up the gap surrounded by the second connection portion 632, which is beneficial to improve stability of the gate isolation structure 630.

Since the first connection portion 631 has a conductive function, when the first connection portion 631 penetrates through the first stack structure 610 and the second stack structure 620, if the first connection portion 631 is connected to the first gate layer 611 or the second gate layer 621, the semiconductor device 600 cannot work normally.

Based on this, in some implementations, referring to FIG. 5, the gate isolation structure 630 further includes a third isolation portion 635 and a fourth isolation portion 636 located at two opposite sides of the source layer SL, the third isolation portion 635 is located between the first connection portion 631 and the first stack structure 610, and the fourth isolation portion 636 is located between the first connection portion 631 and the second stack structure 620.

In some examples, the component material of the third isolation portion 635 and the fourth isolation portion 636 may include an insulating material. The insulating material may include one or more of silicon oxide, silicon nitride, silicon oxynitride, and high dielectric constant insulating materials, or may be other suitable insulating materials.

In a plane parallel to the second direction Y and the third direction Z, the third isolation portion 635 may be disposed around the first connection portion 631 and cover the peripheral surface of the first connection portion 631, which is beneficial to prevent the first connection portion 631 from communicating with the first gate layer 611, so that the semiconductor device 600 operates normally, and the storage stability of the semiconductor device 600 is improved.

In a plane parallel to the second direction Y and the third direction Z, the fourth isolation portion 636 may be disposed around the first connection portion 631 and cover the peripheral surface of the first connection portion 631, which is beneficial to prevent the first connection portion 631 from communicating with the second gate layer 621, so that the semiconductor device 600 operates normally, and the storage stability of the semiconductor device 600 is improved.

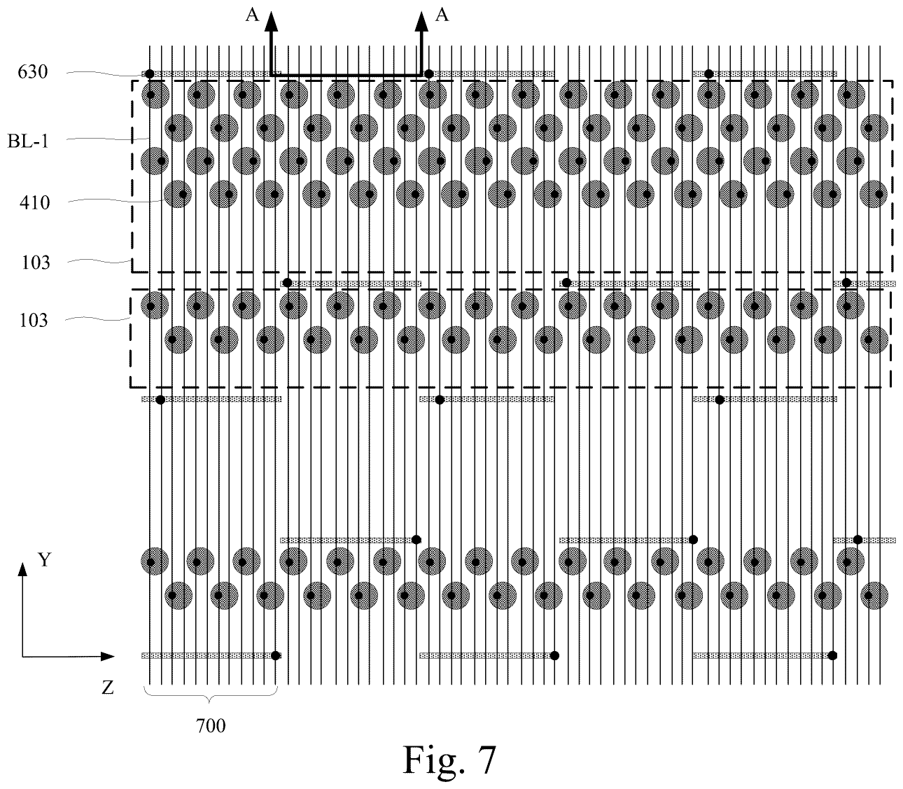

In some implementations, as shown in FIG. 7, there are a plurality of gate isolation structures 630. The plurality of gate isolation structures 630 are arranged in multiple columns along the second direction Y, are arranged in multiple rows along the third direction Z, and two adjacent rows of gate isolation structures 630 are staggered in the third direction Z. It should be noted that two adjacent rows of gate isolation structures 630 may be completely staggered in the third direction Z, for example, projections of two adjacent rows of gate isolation structures 630 in the second direction do not overlap; or two adjacent rows of gate isolation structures 630 may not be completely staggered in the third direction Z, for example, projections of two adjacent rows of gate isolation structures 630 in the second direction partially overlap.

In some examples, the gate isolation structures 630 in odd numbered rows may be arranged in the same manner, and the gate isolation structures 630 in even numbered rows may be arranged in the same manner. It may be construed that projections of the gate isolation structure 630 in odd numbered rows in the second direction Y completely coincide, and projections of the gate isolation structures 630 in even numbered rows in the second direction Y completely coincide. The projections of the gate isolation structures 630 in odd numbered rows in the second direction Y may be connected end to end with the projections of the gate isolation structures 630 in even numbered rows in the second direction Y.

By disposing a plurality of rows and a plurality of columns of gate isolation structures 630 in this implementation, the plurality of first bit lines BL-1 may be connected to the plurality of second bit lines BL-2 in one-to-one correspondence. Moreover, the first stack structure 610 and the second stack structure 620 may be separated into a plurality of memory blocks 103 by the plurality of rows and the plurality of columns of gate isolation structures 630.

In some implementations, as shown in FIG. 5 and FIG. 7, there are a plurality of first bit lines BL-1, and the plurality of first bit lines BL-1 are sequentially arranged at intervals along the third direction Z. One first bit line BL-1 is connected to one end of one second connection portion 632. There are a plurality of second bit lines BL-2, and the plurality of second bit lines BL-2 are sequentially arranged at intervals along the third direction Z. One second bit line BL-2 is connected to the other end of the one second connection portion 632. The orthographic projections of the first bit line BL-1 and the second bit line BL-2 connected to the same second connection portion 632 in the first direction X coincide or partially overlap.

In this implementation, the first bit line BL-1 and the second bit line BL-2 disposed oppositely in the first direction may be connected to the second connection portion 632 of the same gate isolation structure 630. The plurality of first bit lines BL-1 are connected to the plurality of gate isolation structures 630 in one-to-one correspondence. The plurality of second bit lines BL-2 are connected to the plurality of gate isolation structures 630 in one-to-one correspondence.

In some examples, the number of rows and the number of columns of the plurality of gate isolation structures 630 may be designed according to the number of the first bit lines BL-1 and the number of the second bit lines BL-2, so that the plurality of rows and the plurality of columns of gate isolation structures 630 can connect the plurality of first bit lines BL-1 to the plurality of second bit lines BL-2 in one-to-one correspondence.

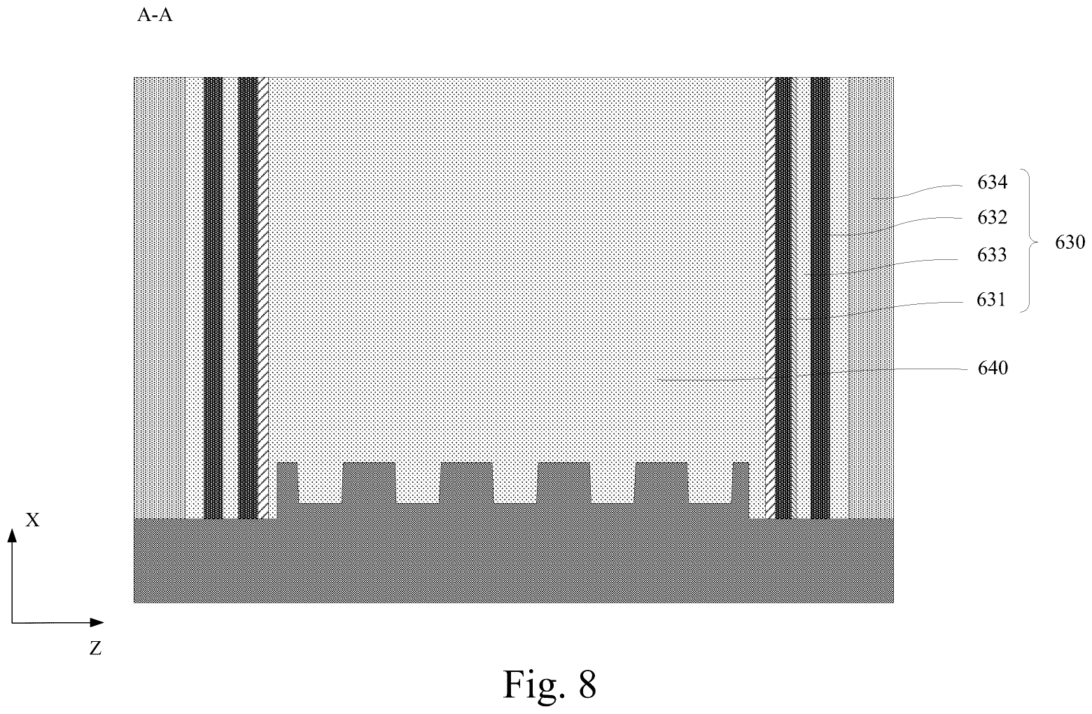

In some implementations, as shown in FIG. 7 and FIG. 8, the semiconductor device 600 further includes a dielectric structure 640, the dielectric structure 640 penetrates through the first stack structure 610, the source layer SL and the second stack structure 620 along the first direction X, and at least one dielectric structure 640 is disposed between two adjacent gate isolation structures 630 along the third direction Z.

At least one dielectric structure 640 being disposed between two adjacent gate isolation structures 630 may be construed that one dielectric structure 640 is disposed between two adjacent gate isolation structures 630, or a plurality of dielectric structures 640 are disposed between two adjacent gate isolation structures 630.

Since the plurality of rows and the plurality of columns of the gate isolation structures 630 separate the first stack structure 610 and the second stack structure 620 into multiple memory blocks 103, there is a certain interval between two adjacent gate isolation structures 630 in the third direction Z. If adjacent memory blocks 103 are connected, a single memory block 103 cannot be selected, so that the semiconductor device 600 cannot work normally.

In order to better isolate adjacent memory blocks 103, in this implementation, a dielectric structure 640 is disposed between two adjacent gate isolation structures 630. The dielectric structure 640 is composed of an insulating material, such as silicon oxide. Through the above arrangement, it is beneficial to improve the isolation effect of the two adjacent memory blocks 103, to prevent the two adjacent memory blocks 103 from being connected, to enable the semiconductor device 600 to operate normally, and is beneficial to improve the storage stability of the semiconductor device 600.

It should be noted that the dielectric structure 640 is located between two adjacent gate isolation structures 630 along the third direction Z, and in order to further improve the isolation effect between two adjacent memory blocks 103, two ends of the dielectric structure 640 along the third direction Z may be respectively in contact with the two gate isolation structures 630.

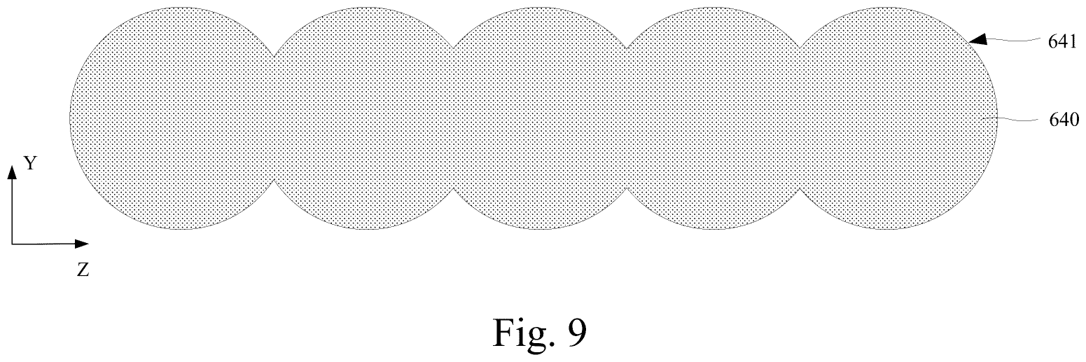

In some implementations, as shown in FIG. 8 and FIG. 9, in a plane parallel to the second direction Y and the third direction Z, the contour edge of the cross section of the dielectric structure 640 includes at least one arc-shaped edge 641.

In some examples, referring to FIG. 9, in a plane parallel to the second direction Y and the third direction Z, the contour edge of a cross section of the dielectric structure 640 may include a plurality of arc-shaped edges 641 connected end to end. Among the plurality of arc-shaped edges 641, radians of any two arc-shaped edges 641 may be the same or different, which is not limited in the present disclosure.

Through the above arrangement, the sizes of the dielectric structure 640 in the second direction Y and the third direction Z can be adjusted by designing the position and the radian of the arc-shaped edges 641. In this way, the dielectric structure 640 may be better adapted to the gap between two adjacent gate isolation structures 630 along the third direction Z, which is beneficial to isolate the mutual interference between two adjacent memory blocks 103 along the second direction Y and to improve the storage stability of the semiconductor device 600.

In some implementations, as shown in FIG. 5 and FIG. 7, the plurality of channel structures 410 are arranged in a plurality of rows along the third direction Z, the plurality of channel structures 410 are arranged in a plurality of columns along the second direction Y, and two adjacent rows of channel structures 410 are staggered in the third direction Z. Here, two adjacent rows of channel structures 410 may be completely staggered in the third direction Z, or two adjacent rows of channel structures 410 may not be completely staggered in the third direction Z. When two adjacent rows of channel structures 410 may be completely staggered in the third direction Z, projections of the two adjacent rows of channel structures 410 in the second direction Y do not overlap. When two adjacent rows of channel structures 410 may not be completely staggered in the third direction Z, projections of the two adjacent rows of channel structures 410 in the second direction partially overlap.

Along the second direction Y, a plurality of rows of channel structures 410 are disposed between two adjacent rows of gate isolation structures 630. Among the plurality of rows of channel structures 410, one first bit line BL-1 is connected to at least one channel structure 410, and one second bit line BL-2 is connected to at least one channel structure 410. In some examples, among the plurality of channel structures 410, one first bit line BL-1 is connected to one channel structure 410, and one second bit line BL-2 is connected to one channel structure 410. That is, the plurality of first bit lines BL-1 are connected to the plurality of channel structures 410 in one-to-one correspondence, and the plurality of second bit lines BL-2 are connected to the plurality of channel structures 410 in one-to-one correspondence. Alternatively, one first bit line BL-1 is connected to one channel structure 410 in each memory block 103, and multiple channel structures 410 connected to the same first bit line BL-1 are located in the same column; one second bit line BL-2 is connected to one channel structure 410 in each memory block 103, and multiple channel structures 410 connected to the same second bit line BL-2 are located in the same column.

It should be noted that the number of the channel structures 410 in each memory block 103 may be the same or different, for example, the memory block 103 may include channel structures 410 such as 2 rows, 4 rows, 6 rows or 8 rows, which is not limited in the present disclosure.

Through the above arrangement, the plurality of rows and the plurality of columns of channel structures 410 may be connected to the plurality of first bit lines BL-1 in one-to-one correspondence, and the plurality of rows and the plurality of columns of channel structures 410 may be connected to the plurality of second bit lines BL-2 in one-to-one correspondence, so that the channel structures 410 are controlled and operated through the first bit lines BL-1 and the second bit lines BL-2.

In addition, two adjacent rows of channel structures 410 are staggered in the third direction Z, which is beneficial to improve the density of the plurality of channel structures 410 and improve the storage density of the semiconductor device 600.

In some implementations, as shown in FIG. 7, the plurality of first bit lines BL-1 constitute a plurality of first bit line groups 700, and the first bit line group 700 includes at least two adjacent first bit lines BL-1. In the first direction X, respective first bit lines BL-1 in the first bit line group 700 overlaps with respective gate isolation structures 630 located in the same column.

The first bit line group 700 including at least two adjacent first bit lines BL-1 may be construed that one first bit line group 700 may include two or more adjacent first bit lines BL-1.

Each of the first bit lines BL-1 in the first bit line group 700 overlaps with each of the gate isolation structures 630 located in the same column in the first direction X. For example, referring to FIG. 7, each of the first bit lines BL-1 in one first bit line group 700 overlaps with respective gate isolation structures 630 located in the first column in the first direction X. That is, the number of the first bit lines BL-1 overlapping in the first direction X with respective gate isolation structures 630 located in the same column is the same.

Two ends of the gate isolation structure 630 along the first direction X are respectively connected to the first bit line BL-1 and the second bit line BL-2, so that the plurality of second bit lines BL-2 may be disposed in one-to-one correspondence with the plurality of first bit lines BL-1. Therefore, the number of the second bit lines BL-2 overlapping in the first direction X with respective gate isolation structures 630 located in the same column is also the same.

In addition, in order to connect all the first bit lines BL-1 of the first bit line group 700 with their corresponding second bit lines BL-2, the number of one column of gate isolation structures 630 overlapping in the first direction X the first bit line group 700 may be the same as the number of the first bit lines BL-1 included in the first bit line group 700. For example, if the first bit line group 700 includes n first bit lines BL-1, the number of one column of gate isolation structures 630 overlapping in the first direction X the first bit line group 700 is also n, one end of one gate isolation structure 630 is connected to one first bit line BL-1, and the other end of the one gate isolation structure 630 is connected to one second bit line BL-2.

Through the above arrangement, the number of gate isolation structures 630 in one column of gate isolation structures 630 can be set according to the number of the first bit lines BL-1, and then the number of rows and the number of columns of the gate isolation structures 630 can be set, so as to design the arrangement of the gate isolation structures 630.

In some implementations, as shown in FIG. 7, one gate isolation structure 630 in one column of gate isolation structures 630 overlapping the first bit line group 700 is connected to one first bit line BL-1 in the first bit line group 700.

One column of gate isolation structures 630 may be connected to all the first bit lines BL-1 in the first bit line group 700 in a one-to-one correspondence, so that the first bit line BL-1 is connected to its corresponding second bit line BL-2, to achieve the electrical connection between the first bit line BL-1 and the second bit line BL-2 without disposing other additional conductive structure, which is beneficial to control the size of the semiconductor device 600 in the second direction Y not to increase and is beneficial to the miniaturization development of the semiconductor device 600. In addition, the above arrangement can reduce the metal lines, reduce the manufacturing cost of the semiconductor device 600, and is beneficial to simplify the circuit design of the semiconductor device 600 and simplify the manufacturing process.

In some implementations, as shown in FIG. 7, the plurality of gate isolation structures 630 have the same size in the third direction Z. That is, the lengths of the plurality of gate isolation structures 630 in the third direction Z are the same. Through the above arrangement, the number of the first bit lines BL-1 connected to each column of gate isolation structures 630 may be the same, which is beneficial to configure the number and arrangement of the gate isolation structures 630 according to the number of the first bit lines BL-1, and is beneficial to simplify the difficulty of the arrangement design of the gate isolation structures 630. Moreover, each of the gate isolation structures 630 has the same size in the third direction Z, which is beneficial to simplify the manufacturing process.

In some implementations, as shown in FIG. 5, the semiconductor device 600 further includes a first contact 701 and a second contact 702. In the first direction X, two ends of the first contact 701 are respectively connected to the first bit line BL-1 and the second connection portion 632. In the first direction, two ends of the second contact 702 are respectively connected to the second bit line BL-2 and the second connection portion 632.

In some examples, the component material of the first contact 701 and the second contact 702 may include conductive materials. The conductive material includes, but is not limited to, one or more of tungsten (W), cobalt (Co), copper (Cu), aluminum (Al), polysilicon, doped silicon, and silicide, or may be other suitable conductive materials.

In some examples, the width, in the second direction Y, of the end of the first contact 701 close to the first bit line BL-1 may be greater than the width, in the second direction Y, of the end of the first contact 701 close to the second connection portion 632. Through the above arrangement, it is beneficial to improve the preparation window of the first contact 701, making it easier for the two ends of the first contact 701 in the first direction X to be respectively connected to the first bit line BL-1 and the second connection portion 632.

In some examples, the width, in the second direction Y, of the end of the second contact 702 close to the second bit line BL-2 may be greater than the width, in the second direction Y, of the end of the second contact 702 close to the second connection portion 632. Through the above arrangement, it is beneficial to improve the preparation window of the second contact 702, making it easier for the two ends of the second contact 702 in the first direction X to be respectively connected to the second bit line BL-2 and the second connection portion 632.

In some examples, there may be a plurality of first contacts 701, for example, in this implementation, there are two first contacts 701. The plurality of first contacts 701 may be disposed at intervals along the peripheral side of the second connection portion 632. The plurality of first contacts 701 are disposed to connect the first bit line BL-1 and the second connection portion 632, which is beneficial to reduce the resistance between the first contacts 701 and the first bit line BL-1, and also beneficial to reduce the resistance between the first contacts 701 and the second connection portion 632, thereby being beneficial to improve the electrical signal strength between the first bit line BL-1 and the second connection portion 632.

In this implementation, by disposing the first contact 701, it is convenient to connect the first bit line BL-1 with the second connection portion 632, and by disposing the second contact 702, it is convenient to connect the second bit line BL-2 with the second connection portion 632, thereby achieving electrical connection between the first bit line BL-1 and the second bit line BL-2, and facilitating electrical signal transmission between the first bit line BL-1 and the second bit line BL-2.

In some implementations, as shown in FIG. 5, the channel structure 410 includes a channel layer 411 and a functional layer 412 disposed around a portion of the channel layer 411. The channel layer 411 may be made of a semiconductor material including, but not limited to, amorphous silicon, polycrystalline silicon, or monocrystalline silicon. The voltage provided by the first gate layer 611 or the second gate layer 621 can control the carriers (electrons or holes) in the channel layer 411 to move or stop.

The functional layer 412 is disposed around a portion of the channel layer 411. The functional layer 412 may include a tunneling layer 4121, a storage layer 4122, and a blocking layer 4123 sequentially disposed along a direction away from the channel layer 411. The carriers in the channel layer 411 may tunnel into the storage layer 4122 through the tunneling layer 4121, the storage layer 4122 is configured to store the carriers, and the blocking layer 4123 is configured to prevent the carriers from overflowing.

The material of the tunneling layer 4121 may include, but is not limited to, one or more of silicon oxide and silicon oxynitride. In some examples, the tunneling layer 4121 may be a single-layer dielectric, such as a silicon oxide layer. In other examples, the tunneling layer 4121 may be a composite dielectric layer, such as a deck structure of a first silicon oxide layer, a first silicon oxynitride layer, a second silicon oxynitride layer, and a second silicon oxide layer.

The material of the blocking layer 4123 may include one or more of silicon oxide, silicon nitride, and a high dielectric constant material. In some examples, the blocking layer 4123 may be a single-layer dielectric, such as a silicon oxide layer. In other examples, the blocking layer 4123 may be a composite dielectric layer, such as a deck structure of a silicon nitride layer and an aluminum oxide layer.

The storage layer 4122 is configured to store carriers. The material of the storage layer 4122 may include silicon nitride, or may include other materials suitable for storing carriers, which is not limited herein.

In this implementation, the channel layer 411 penetrates through the first stack structure 610, the source layer SL and the second stack structure 620 along the first direction X and is in contact with the source layer SL. The functional layer 412 includes a first portion 4124 and a second portion 4125 on opposite sides of the source layer SL, the first portion 4124 penetrates through the first stack structure 610 and is in contact with the source layer SL, and the second portion 4125 penetrates through the second stack structure 620 and is in contact with the source layer SL. Here, it can be construed that the source layer SL separates the functional layer 412 into a first portion 4124 and a second portion 4125.

Through the above arrangement, by increasing the number of stacked layers of the first stack structure 610 or the second stack structure 620, the length of the channel structure 410 in the first direction X can be increased, and the storage capacity of the channel structure 410 can be increased. Moreover, the source layer SL can be connected to the channel layer 411, so that the source layer SL applies a voltage to the channel layer 411. The storage capacity of the channel structure 410 is increased, meanwhile the problem of weak current intensity in the channel structure 410 due to increasing the length of the channel structure 410 is improved.

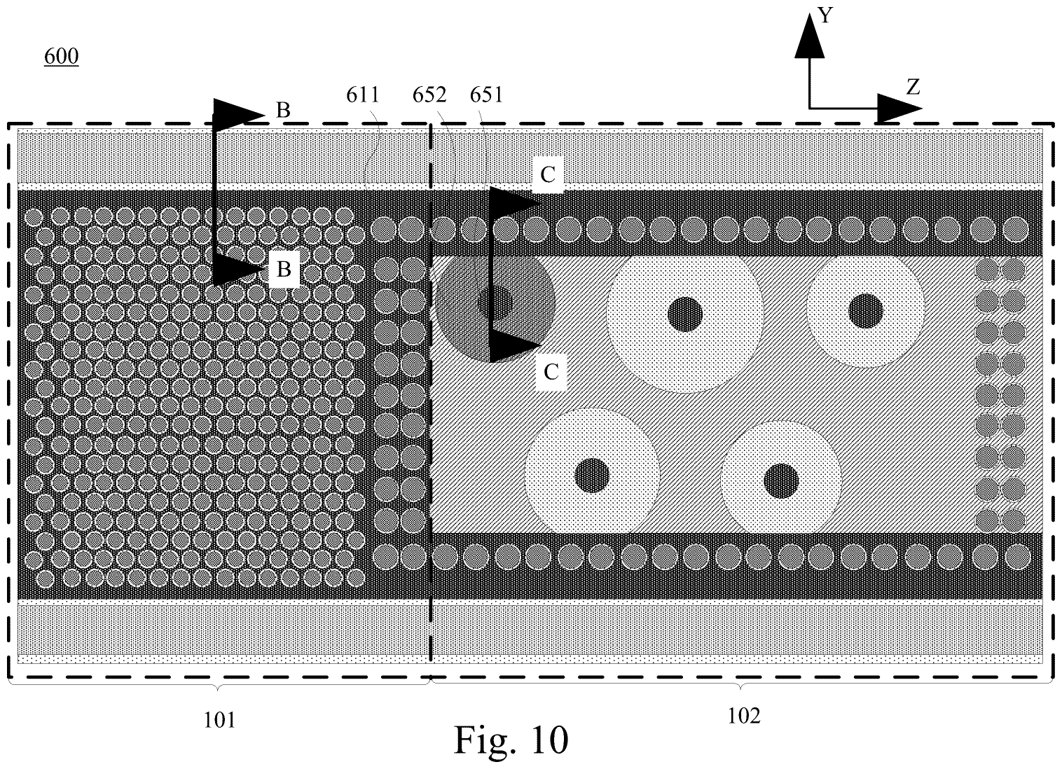

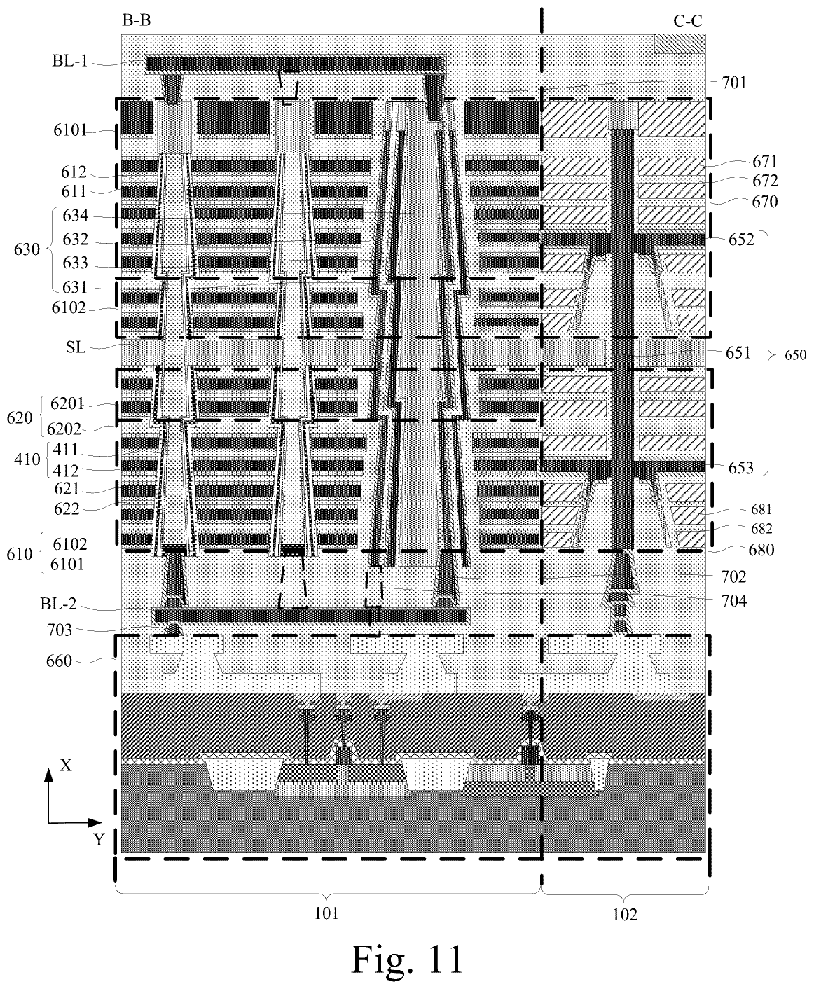

In some implementations, referring to FIG. 10 and FIG. 11, the first stack structure 610 may include a first sub-stack structure 6101 and a second sub-stack structure 6102 stacked along the first direction X, the second stack structure 620 may include a third sub-stack structure 6201 and a fourth sub-stack structure 6202 stacked along the first direction X, and the third sub-stack structure 6201 is closer to the second sub-stack structure 6102 than is the fourth sub-stack structure 6202. The source layer SL is located between the second sub-stack structure 6102 and the third sub-stack structure 6201.

It should be noted that the first stack structure 610 and the second stack structure 620 may include the same number of sub-stack structures (as shown in FIG. 11). However, the first stack structure 610 and the second stack structure 620 may further include different numbers of sub-stack structures, which is not limited in the present disclosure.

In some examples, the semiconductor device 600 may continue to form one or more stack structures on a side of the first sub-stack structure 6101 away from the second sub-stack structure 6102, to increase the length of the channel structure 410 in the first direction X, thereby increasing the storage capacity of the semiconductor device 600. Alternatively, the semiconductor device 600 may further form one or more stack structures on a side of the fourth sub-stack structure 6202 away from the third sub-stack structure 6201, to increase the length of the channel structure 410 in the first direction X, thereby increasing the storage capacity of the semiconductor device 600.

Through the above arrangement, it is beneficial to further increase the length of the channel structure 410 in the first direction X, thereby increasing the storage capacity of the semiconductor device 600. At the same time, the source layer SL can drive the channel structure 410 up and down simultaneously, which shortens the length of the channel structure 410 to be driven by the source layer SL, increase the storage capacity of the channel structure 410, improves the problem of weak current intensity in the channel structure 410 due to increasing the length of the channel structure 410, and thus improves the device performance such as the storage speed and the response speed of the semiconductor device 600.

At present, users pursue a three-dimensional memory with large capacity and small volume. Referring to FIG. 1, in order to increase the capacity of the three-dimensional memory 10, the number of stacked layers of the gate lines G increases. However, one gate line G is connected to one gate line contact G-CNT. With the increase of the number of layers of the gate line G, the number of the gate line contacts G-CNT coupled to the gate line G also increases, so the space occupied by the gate line contacts G-CNT increases, resulting in an increase of the size of the three-dimensional memory in the third direction Z, which is not beneficial to improve the storage density of the three-dimensional memory 10, and is not beneficial to the development of the three-dimensional memory 10 towards a smaller volume.

Based on this, in some implementations, as shown in FIG. 10 and FIG. 11, the semiconductor device 600 further includes a plurality of connection structures 650, the plurality of connection structures 650 are located on a side of the first stack structure 610 and the second stack structure 620, one connection structure 650 is connected to at least one first gate layer 611, and one connection structure 650 is connected to at least one second gate layer 621.

It should be noted that FIG. 11 is a spliced view, the left side of the dotted line in FIG. 11 is a cross-sectional view along B-B in FIG. 10, and the right side of the dotted line in FIG. 11 is a cross-sectional view along C-C in FIG. 10.

In this implementation, the semiconductor device 600 may include a first region 101 and a second region 102 adjacent to each other along the third direction Z. The first stack structure 610 and the second stack structure 620 may both be located in the first region 101, and the connection structure 650 may be located in the second region 102. The connection structure 650 being connected to at least one first gate layer 611 may be construed as the connection structure 650 being connected to one first gate layer 611, or the connection structure 650 being connected to a plurality of first gate layers 611. The connection structure 650 being connected to at least one second gate layer 621 may be construed as the connection structure 650 being connected to one second gate layer 621, or the connection structure 650 being connected to a plurality of second gate layers 621. The present disclosure is explained by taking the connection structure 650 being connected to one first gate layer 611 and being connected to one second gate layer 621 as an example.

In some examples, the component material of the connection structure 650 may include a conductive material. The conductive material includes, but is not limited to, one or more of tungsten (W), cobalt (Co), copper (Cu), aluminum (Al), polysilicon, doped silicon, and silicide, or may be other suitable conductive materials.

In this implementation, one connection structure 650 may be connected to one first gate layer 611 in the first stack structure 610 and one second gate layer 621 in the second stack structure 620. In addition, the connection structure 650 may be connected to the peripheral interconnection layer 130, to achieve the transmission of electrical signals between the first gate layer 611 and the peripheral interconnection layer 130 and between the second gate layer 621 and the peripheral interconnection layer 130. In some examples, the connection structure 650 may be connected to the peripheral interconnection layer 130 through a contact. In this implementation, one first gate layer 611 and one second gate layer 621 may share one connection structure 650, and compared with that the first gate layers 611 are connected to the gate line contacts G-CNT in one-to-one correspondence and the second gate layers 621 are connected to the gate line contacts G-CNT in one-to-one correspondence, the number of the connection structures 650 is less than the number of the gate line contacts G-CNT. Therefore, the space occupied by the connection structure 650 is smaller than the space occupied by the gate line contact G-CNT, which is beneficial to increase the storage density of the semiconductor device 600 and is beneficial to the miniaturization development of the semiconductor device 600.

In addition, this solution has strong extensibility. For example, when more stack structures are included in the semiconductor device 600, for example, the semiconductor device 600 may include a plurality of stack structures such as 4 stack structures, 6 stack structures, or 8 stack structures. In this case, the connection structure 650 may be connected to one gate layer in each stack structure. Through the above arrangement, even if more stack structures are added, the number of the connection structures 650 will not be increased, and the space occupied by the connection structures 650 will not be increased, which is beneficial to increase the storage density of the semiconductor device 600, and is beneficial to the development of the semiconductor device 600 in the direction of large capacity and small volume.

In some implementations, as shown in FIG. 11, the connection structure 650 includes a connection pillar 651, at least one first connection layer 652, and at least one second connection layer 653. The connecting pillar 651 extends along the first direction X. The first connection layer 652 is parallel to the second direction Y, and one first connection layer 652 connects the connection pillar 651 and one first gate layer 611. The second connection layer 653 is parallel to the second direction Y, and one second connection layer 653 connects the connection pillar 651 and one second gate layer 621.

In this implementation, in the Y-Z plane, the first connection layer 652 may be disposed around the connection pillar 651 and connected to the connection pillar 651. One first connection layer 652 is configured to connect the connection pillar 651 and one first gate layer 611, as shown in FIG. 11. In this implementation, the first gate layer 611 can also extend along the third direction Z; for example, the first gate layer 611 can extend along the third direction Z to the second region 102, while the first connection layer 652 can extend along the second direction Y and the third direction Z, and the first connection layer 652 located in the second region 102 can be connected to the portion of the first gate layer 611 that extends to the second region 102. That is, the first connection layer 652 and the first gate layer 611 can be connected in the second direction Y. It should be noted that the first connection layer 652 is configured to connect the first gate layer 611 and the connection pillar 651, and the specific connection manner of the first connection layer 652 and the first gate layer 611 includes but is not limited to the connection manner provided in this implementation, which is not limited in the present disclosure.

Referring to FIG. 10 and FIG. 11, in the Y-Z plane, the cross section of the connection pillar 651 may be, for example, of a round shape, the cross section of the first connection layer 652 may be, for example, of an annulus shape, the first connection layer 652 may be disposed around the connection pillar 651 and connected to the connection pillar 651, and the outer edge of the first connection layer 652 may be connected to the first gate layer 611.

Identically, in the Y-Z plane, the second connection layer 653 may be disposed around and connected to the connection pillar 651. One second connection layer 653 connects the connection pillar 651 and one second gate layer 621, the second gate layer 621 may extend along the third direction Z to the second region 102, while the second connection layer 653 is parallel to the second direction Y and the third direction Z, the second connection layer 653 may be connected to the portion of the second gate layer 621 that extends to the second region 102; for example, the second connection layer 653 and the second gate layer 621 may be connected in the second direction Y. It should be noted that the second connection layer 653 is configured to connect the second gate layer 621 and the connection pillar 651, and the specific connection manner of the second connection layer 653 and the second gate layer 62 includes but is not limited to the connection manner provided in this implementation, which is not limited in the present disclosure.

In the Y-Z plane, the cross section of the connection pillar 651 may be, for example, of a round shape, the cross section of the second connection layer 653 may be, for example, of an annulus shape, the second connection layer 653 may be disposed around the connection pillar 651 and connected to the connection pillar 651, and the outer edge of the second connection layer 653 may be connected to the second gate layer 621.

It should be noted that the connection structure 650 including at least one first connection layer 652 and at least one second connection layer 653 may be construed such that the connection structure 650 may include one first connection layer 652, or the connection structure 650 may include a plurality of first connection layers 652; the connection structure 650 may include one second connection layer 653, or the connection structure 650 may include a plurality of second connection layers 653. When the connection structure 650 includes a plurality of first connection layers 652, the plurality of first connection layers 652 may be disposed at intervals along the first direction X; when the connection structure 650 includes a plurality of second connection layers 653, the plurality of second connection layers 653 may be disposed at intervals along the first direction X. The implementation herein is explained by taking the connection structure 650 including one first connection layer 652 and one second connection layer 653 as an example.

In this implementation, the first connection layer 652 is configured to connect the first gate layer 611 and the connection pillar 651, the second connection layer 653 is configured to connect the second gate layer 621 and the connection pillar 651, and the connection pillar 651 is configured to connect to the peripheral interconnection layer 130 to achieve the transmission of electrical signals between the first gate layer 611 and the peripheral interconnection layer 130 and between the second gate layer 621 and the peripheral interconnection layer 130. Through the above arrangement, one first gate layer 611 and one second gate layer 621 in this implementation may share one connection structure 650, compared with that the first gate layers 611 are connected to the gate line contacts G-CNT in one-to-one correspondence and the second gate layers 621 are connected to the gate line contacts G-CNT in one-to-one correspondence, the number of the connection structures 650 is less than the number of the gate line contacts G-CNT. Therefore, the space occupied by the connection structure 650 is smaller than the space occupied by the gate line contact G-CNT, which is beneficial to increase the storage density of the semiconductor device 600 and is beneficial to the miniaturization development of the semiconductor device 600.

In addition, this solution has strong extensibility. For example, when more stack structures are included in the semiconductor device 600, the semiconductor device 600 may include a plurality of stack structures such as 4 stack structures, 6 stack structures, or 8 stack structures, for example. In this case, the connection structure 650 may be connected to one gate layer in each stack structure by increasing the number of connection layers, for example, adding the third connection layer, the fourth connection layer, and the fifth connection layer. Through the above arrangement, even if more stack structures are added, the number of the connection structures 650 will not be increased, and the space occupied by the connection structures 650 will not be increased either, which is beneficial to increasing the storage density of the semiconductor device 600, and is beneficial to the development of the semiconductor device 600 in the direction of large capacity and small volume.

In some implementations, the first gate layer 611 farthest from the second stack structure 620 among the plurality of first gate layers 611 may be set as the bottom select gate of the first stack structure 610, and the first gate layer 611 closest to the second stack structure 620 among the plurality of first gate layers 611 may be set as the top select gate of the first stack structure 610. With the above arrangement, the semiconductor device 600 may further be selected to read or write the memory node of the first stack structure 610 through the top select gate and the bottom select gate of the first stack structure 610.

Identically, the second gate layer 621 farthest from the first stack structure 610 among the plurality of second gate layers 621 may be set as the top select gate of the second stack structure 620, and the second gate layer 621 closest to the first stack structure 610 among the plurality of second gate layers 621 may be set as the bottom select gate of the second stack structure 620. With the above arrangement, the semiconductor device 600 may further be selected to read or write the memory node of the second stack structure 620 through the top select gate and the bottom select gate of the second stack structure 620.

In a similar fashion, if more stack structures continue to be formed, a top select gate and a bottom select gate may be set among the plurality of gate layers of the stack structures, thereby selecting a memory node in a certain stack structure.

In some implementations, as shown in FIG. 11, the connection pillar 651, the first connection layer 652, and the second connection layer 653 are an integral structure. It can be construed that the connection pillar 651, the first connection layer 652, and the second connection layer 653 are made in one process operation, thereby being beneficial for enhancing the stability of the electrical connection between the connection pillar 651 and the first connection layer 652, and being beneficial for enhancing the stability of the electrical connection between the connection pillar 651 and the second connection layer 653.

In some implementations, as shown in FIG. 11, the semiconductor device 600 further includes a third stack structure 670 and a fourth stack structure 680. The third stack structure 670 is adjacent to the first stack structure 610 along the third direction Z, and the third stack structure 670 includes third dielectric layers 671 and fourth dielectric layers 672 alternately stacked along the first direction X. That is, the third dielectric layers 671 and the fourth dielectric layers 672 alternately disposed along the first direction X are stacked to form a plurality of third dielectric layers 671 and a plurality of fourth dielectric layers 672 spaced apart from each other.

It may be construed that the third stack structure 670 is adjacent to the first stack structure 610 along the third direction Z, and for example, the third stack structure 670 may be located in the second region 102 of the semiconductor device 600. When the first stack structure 610 includes a plurality of sub-stack structures, the third stack structure 670 may also correspondingly include a plurality of sub-stack structures.

The fourth stack structure 680 and the third stack structure 670 are stacked along the first direction X, and the fourth stack structure 680 includes fifth dielectric layers 681 and sixth dielectric layers 682 alternately stacked along the first direction X. That is, the fifth dielectric layers 681 and the sixth dielectric layers 682 alternately disposed along the first direction X are stacked to form a plurality of fifth dielectric layers 681 and a plurality of sixth dielectric layers 682 spaced apart from each other.

It may be construed that the fourth stack structure 680 may be adjacent to the second stack structure 620 along the third direction Z, and for example, the fourth stack structure 680 may be located in the second region 102 of the semiconductor device 600. When the second stack structure 620 includes a plurality of sub-stack structures, the fourth stack structure 680 may also correspondingly include a plurality of sub-stack structures.

The connection pillar 651 penetrates through the third stack structure 670 and the fourth stack structure 680 along the first direction X, at least one third dielectric layer 671 is connected to at least one first connection layer 652, and at least one fifth dielectric layer 681 is connected to at least one second connection layer 653. Here, the first connection layer 652 connected to the third dielectric layer 671 may be connected to the first gate layer 611, and the second connection layer 653 connected to the fifth dielectric layer 681 may be connected to the second gate layer 621.

In some examples, the third dielectric layer 671 may be connected to the first gate layer 611, and the fourth dielectric layer 672 may be connected to the first dielectric layer 612. In addition, the component material of the fourth dielectric layer 672 may the same as that of the first dielectric layer 612, and further, the fourth dielectric layer 672 may be disposed at the same layer as the first dielectric layer 612. Being disposed at the same layer may mean that a plurality of patterns are in the same pattern layer, and the pattern layer refers to a film layer formed by one pattern-constructing process. The pattern-constructing process refers to a process capable of forming at least one pattern having a certain shape. For example, a thin film is formed on a substrate base board by any one of a plurality of film forming processes such as deposition, coating, and sputtering, then the thin film is patterned to form a film layer including at least one pattern, and the film layer is referred to as a pattern layer. The operation of patterning includes: coating photoresist, exposing, developing, etching, and stripping the photoresist or the like. In this implementation, the positional relationships of the plurality of patterns belonging to the same pattern layer are referred to as being disposed at the same layer.

In some examples, the fifth dielectric layer 681 may be connected to the second gate layer 621, and the sixth dielectric layer 682 may be connected to the second dielectric layer 622. In addition, the component material of the sixth dielectric layer 682 may be the same as that of the second dielectric layer 622, and further, the sixth dielectric layer 682 may be disposed at the same layer as the second dielectric layer 622. For example, the component materials of the first dielectric layer 612, the second dielectric layer 622, the fourth dielectric layer 672 and the sixth dielectric layer 682 each are oxide, and the component materials of the third dielectric layer 671 and the fifth dielectric layer 681 each are nitride.

Referring to FIG. 1, when forming the G-CNTs, since each G-CNT needs to penetrate to a different gate layer, the process of forming the G-CNTs is difficult.

In the present implementation, the connection pillar 651 of the connection structure 650 penetrates through the third stack structure 670 and the fourth stack structure 680, and compared with the process of the G-CNTs penetrating to different gate layers, the process of manufacturing the connection structure 650 is less difficult, which, hence, is beneficial for reducing the process difficulty of manufacturing the semiconductor device 600 and improving the manufacturing efficiency of the semiconductor device 600.

In some implementations, as shown in FIG. 11, the source layer SL is located between the third stack structure 670 and the fourth stack structure 680, and the connection pillar 651 penetrates through the source layer SL. The semiconductor device 600 further includes a third isolation layer 654 that is disposed around the connection pillar 651 and is located between the connection pillar 651 and the source layer SL. The third isolation layer 654 may cover the peripheral surface of the connection pillar 651, so that the connection pillar 651 is isolated from the source layer SL, thereby preventing the connection pillar 651 from being electrically connected to the source layer SL, which is beneficial for protecting the normal operation of the semiconductor device 600 and enhancing the storage stability of the semiconductor device 600.

In some implementations, as shown in FIG. 11, the connection structure 650 further includes a fourth isolation layer 655 and a fifth isolation layer 656. The fourth isolation layer 655 is located on a side of the first connection layer 652 close to the second connection layer 653, and the fourth isolation layer 655 is disposed around the connection pillar 651; for example, the fourth isolation layer 655 may cover the peripheral surface of the connection pillar 651 to isolate the connection pillar 651 to prevent leakage current from being generated between the connection pillar 651 and other conductive structures, which is beneficial for enhancing the storage stability of the semiconductor device 600.

In addition, the fifth isolation layer 656 is located on a side of the second connection layer 653 away from the first connection layer 652, and the fifth isolation layer 656 is disposed around the connection pillar 651; for example, the fifth isolation layer 656 may cover the peripheral surface of the connection pillar 651 to isolate the connection pillar 651 to prevent leakage current from being generated between the connection pillar 651 and other conductive structures, which is beneficial for enhancing the storage stability of the semiconductor device 600.

In some implementations, as shown in FIG. 11, the size in the second direction of the end of the fourth isolation layer 655 away from the first connection layer 652 is greater than the size in the second direction of the end of the fourth isolation layer 655 proximate to the first connection layer 652. In the second direction Y, the fourth isolation layer 655 has a certain thickness, and the thickness of the end of the fourth isolation layer 655 close to the connection pillar 651 may be greater than the thickness of the end of the fourth isolation layer 655 close to the first connection layer 652. In this way, it is beneficial for further improving the isolation effect on the connection pillar 651 close to the end of the connection pillar 651.

Continuing to refer to FIG. 11, in the second direction Y, the fifth isolation layer 656 has a certain thickness, and the thickness of the end of the fifth isolation layer 656 away from the connection pillar 651 may be greater than the thickness of the end of the fifth isolation layer 656 close to the connection pillar 651. In this way, it is beneficial for further improving the isolation effect of the fifth isolation layer 656 on the connection pillar 651 away from the end of the connection pillar 651.

In some examples, the component materials of the fourth isolation layer 655 and the fifth isolation layer 656 may include an insulating material. The insulating material may be, for example, one or more of silicon oxide, silicon nitride, and high dielectric constant insulating materials, or may be other insulating materials. The component materials of the fourth isolation layer 655 and the fifth isolation layer 656 may be the same or different.

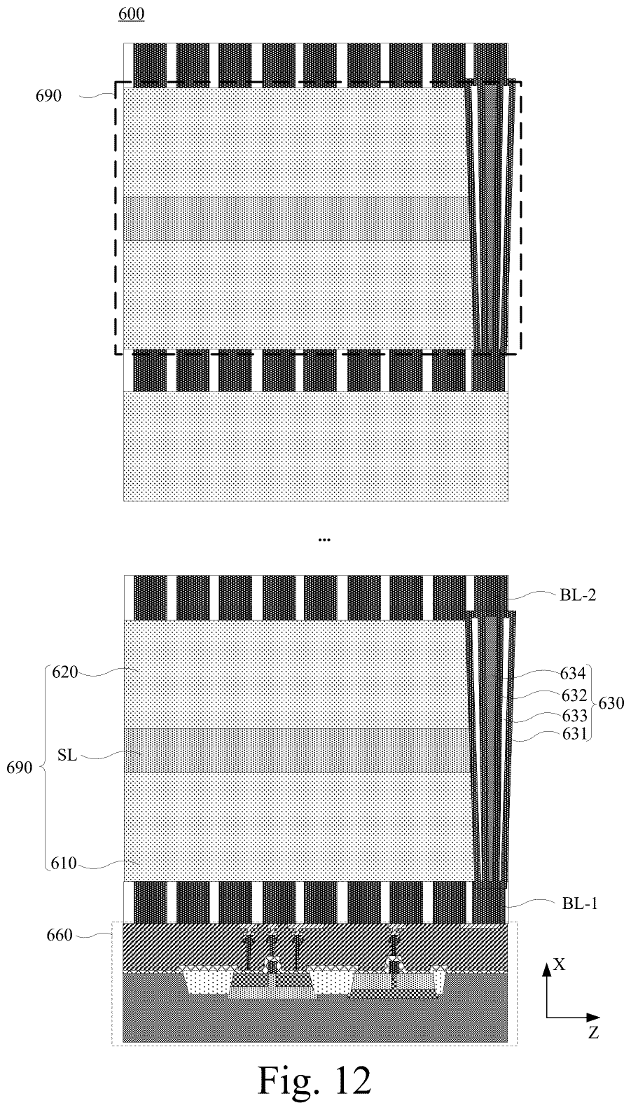

In some implementations, as shown in FIG. 12, the first stack structure 610, the source layer SL, and the second stack structure 620 together constitute one repeating structure 690. There may be a plurality of repeating structures 690 stacked along the first direction X. The source layers SL in the plurality of repeating structures 690 may be interconnected to facilitate the transmission of electrical signals between the plurality of repeating structures 690.

It should be noted that the number of stacked layers of the plurality of repeating structures 690 may be the same or different, and it may be construed that the number of stacked layers of the plurality of first stack structures 610 may be the same or different, and the number of stacked layers of the plurality of second stack structures 620 may be the same or different, which is not limited in the present disclosure.

In some implementations, as shown in FIGS. 11 and 12, the semiconductor device 600 further includes a peripheral circuit structure 660. The peripheral circuit structure 660 is located on a side of the first bit line BL-1 away from the first stack structure 610 and is connected to the first bit line BL-1, and the peripheral circuit structure 660 may be connected to the first connection portion 631.

In some examples, the peripheral circuit structure 660 may include at least one layer of a circuit structure and is coupled to device structures such as the channel structure 410, the first bit line BL-1 (or the second bit line BL-2), the connection structure 650 through the circuit structure (for example, metal lines) and other interconnection structures, to achieve the transmission of electrical signals between the peripheral circuit structure 660 and other device structures. The peripheral circuit structure 660 may further include an interlayer dielectric to isolate the circuit structure. The interlayer dielectric may be made of a dielectric material. The dielectric material includes, but is not limited to, silicon oxide, silicon nitride, silicon oxynitride, a low-k dielectric, or any combination thereof.

Through the above arrangement, the peripheral circuit structure 660 may transmit electrical signals to and from the source layer SL through the first connection portion 631, and the peripheral circuit structure 660 may transmit electrical signals to and from the first bit line BL-1 and the second bit line BL-2.

Among the plurality of repeating structures 690, the repeating structure 690 at the topmost or bottommost end is electrically connected to the peripheral circuit structure 660. That is, the plurality of repeating structures 690 may share one peripheral circuit structure 660, so as to perform operations such as storing or reading on the channel structure 410 in the plurality of repeating structures 690.

In some implementations, as shown in FIG. 11, the semiconductor device 600 further includes a third contact 703 and a fourth contact 704. In the first direction X, two ends of the third contact 703 are respectively connected to the second bit line BL-2 and the peripheral circuit structure 660. In the first direction X, two ends of the fourth contact 704 are respectively connected to the first connection portion 631 and the peripheral circuit layer.

In some examples, the component materials of the third contact 703 and the fourth contact 704 may include a conductive material. The conductive material includes, but is not limited to, one or more of tungsten (W), cobalt (Co), copper (Cu), aluminum (Al), polysilicon, doped silicon, and silicide, or may be other suitable conductive materials.

In this implementation, by disposing the third contact 703, it is convenient to connect the second bit line BL-2 with the peripheral circuit structure 660, and by disposing the fourth contact 704, it is convenient to connect the first connection portion 631 with the peripheral circuit structure 660, thereby achieving the transmission of electrical signals between the second bit line BL-2 and the peripheral circuit structure 660, and achieving the transmission of electrical signals between the source layer SL and the peripheral circuit structure 660.

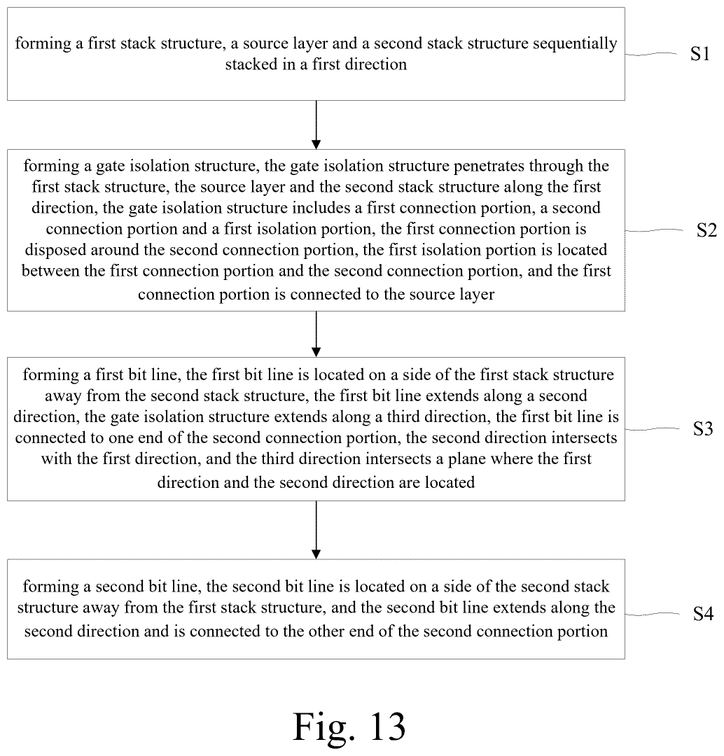

Some implementations of the present disclosure further provide a method of manufacturing a semiconductor device which is illustrated below with reference to FIGS. 13-19.

FIG. 13 is a flow chart of a method of manufacturing a semiconductor device according to some implementations. As shown in FIG. 13, the method of manufacturing the semiconductor device provided by some implementations of the present disclosure includes operations S1 to S4.

At operation S1, the method may include forming a first stack structure, a source layer and a second stack structure sequentially stacked in the first direction.

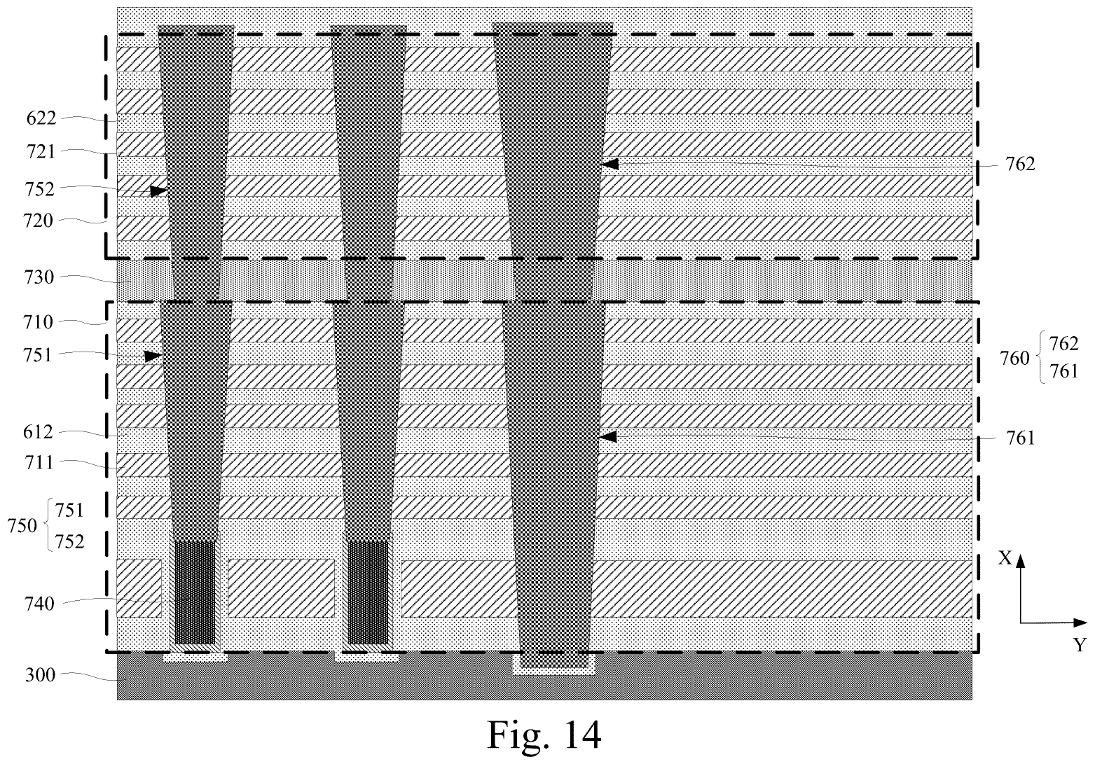

In this operation, referring to FIG. 14, a first deck structure may be formed on the semiconductor layer, and the first deck structure includes a plurality of first sacrificial layers and a plurality of first dielectric layers alternately stacked along the first direction X.

In some examples, the first dielectric layers 612 and the first sacrificial layers may be alternately formed on the semiconductor layer 300 by a deposition process. The deposition process includes, but is not limited to, one or more thin film deposition processes of physical vapor deposition (PVD), chemical vapor deposition (CVD), and atomic layer deposition (ALD).

The semiconductor layer 300 may include silicon (e.g., monocrystalline silicon, polycrystalline silicon), silicon germanium (SiGe), gallium arsenide (GaAs), germanium (Ge), silicon-on-insulator (SOI), and/or any other suitable semiconductor material.

The component materials of the first dielectric layers 612 and the first sacrificial layers 711 may include an insulating material, and the insulating material may include one or more of silicon oxide, silicon nitride, silicon oxynitride, and high dielectric constant insulating materials, or may be other suitable insulating materials.

Since the first sacrificial layer 711 need to be removed in the subsequent manufacturing operations, the component material of the first sacrificial layer 711 needs to be different from the component material of the first dielectric layer 612, so as to prevent the first dielectric layer 612 from being damaged when the first sacrificial layer 711 is removed. This implementation is explained taking the component material of the first dielectric layer 612 being silicon oxide and the component material of the first sacrificial layer 711 being silicon nitride as an example.

Referring to FIG. 14, after the first deck structure 710 is formed, a portion of the first deck structure 710 is removed to form a first channel hole 751 and a first gate slit 761, both the first channel hole 751 and the first gate slit 761 penetrate through the first deck structure 710, and the first gate slit 761 is located on a side of the first channel hole 751 along the second direction Y.

In this operation, the first channel hole 751 and the first gate slit 761 may be formed by any suitable process. For example, a patterned photoresist layer may be formed on the first deck structure 710. The patterned photoresist layer can expose a portion of the first deck structure 710 for forming the first channel hole 751 and the first gate slit 761. A suitable etching process may be performed to remove a portion of the first deck structure 710 for forming the first channel hole 751 and the first gate slit 761. For example, the etching process may include a dry etching process.

After the first channel hole 751 and the first gate slit 761 are formed, the patterned photoresist layer on the first deck structure 710 may be removed, for example, the surface of the first deck structure 710 may be planarized by chemical mechanical polish (CMP) to remove the patterned photoresist layer on the first deck structure 710.

After the patterned photoresist layer on the first deck structure 710 is removed, a deposition process may be adopted to fill the first channel hole 751 and the first gate slit 761 with a sacrificial material (such as carbon), so as to continue to form a second sacrificial layer 730 on the first deck structure 710 in a subsequent manufacturing operation.

It should be noted that, in order to facilitate determining the position of the first channel hole 751, a structural pile 740 may be formed on the semiconductor layer before forming the first deck structure 710. When the first channel hole 751 is subsequently formed, the first channel hole 751 may penetrate through the first deck structure 710 to the structural pile 740, so as to determine the position of the first channel hole 751.

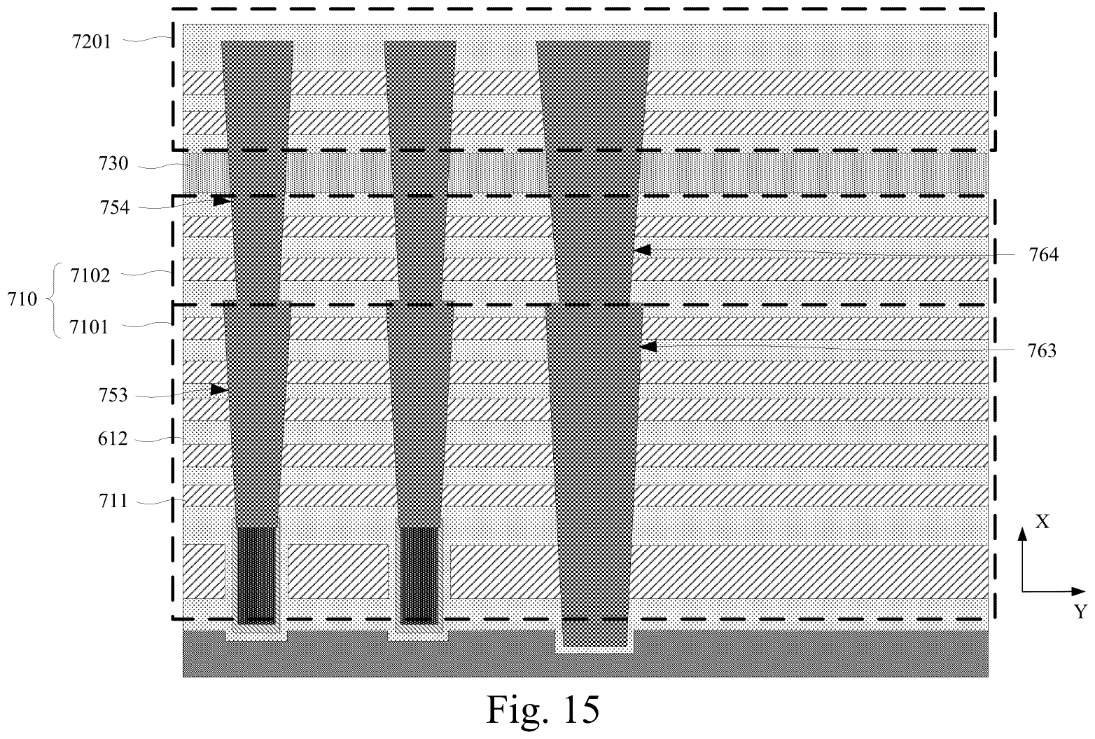

Referring to FIG. 15, after the first channel hole 751 and the first gate slit 761 are formed, a second sacrificial layer 730 is formed on the first deck structure 710, and the second sacrificial layer 730 and the first deck structure 710 are stacked along the first direction X.

In this operation, the second sacrificial layer 730 may be formed on the first deck structure 710 by using one or more thin film deposition processes including, but not limited to, PVD, CVD, and ALD. In some examples, the material of the second sacrificial layer 730 may be polysilicon.

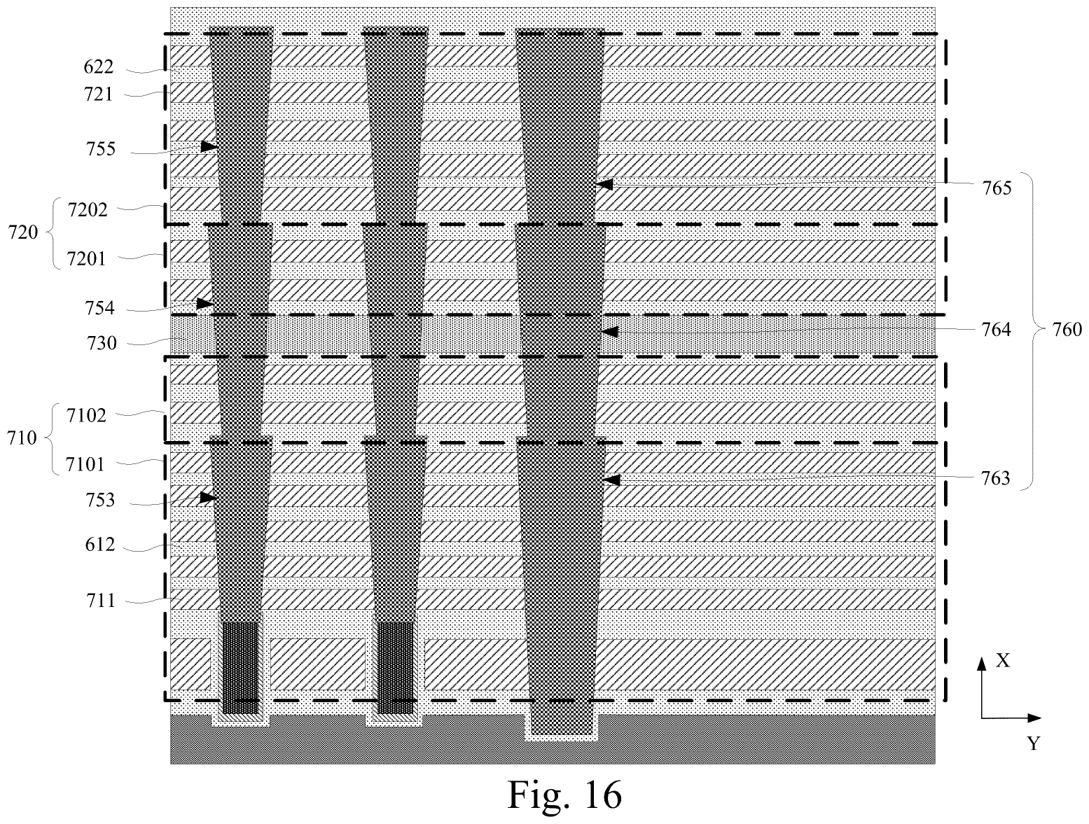

Referring to FIG. 15 and FIG. 16, after the second sacrificial layer 730 is formed, a second deck structure 720 is formed on the second sacrificial layer 730, the second deck structure 720 is located on a side of the second sacrificial layer 730 away from the first deck structure 710, and the second deck structure 720 includes a plurality of third sacrificial layers 721 and a plurality of second dielectric layers 622 alternately stacked in the first direction X.

In this operation, the second dielectric layer 622 and the third sacrificial layer 721 may be alternately formed on the second sacrificial layer 730 by using one or more thin film deposition processes including, but not limited to, PVD, CVD, and ALD.

The component materials of the second dielectric layer 622 and the third sacrificial layer 721 may include an insulating material, and the insulating material may include one or more of silicon oxide, silicon nitride, silicon oxynitride, and high dielectric constant insulating materials, or may be other suitable insulating materials.

Since the third sacrificial layer 721 is removed in the subsequent manufacturing operations, the component material of the third sacrificial layer 721 may be different from the component material of the second dielectric layer 622 to prevent the second dielectric layer 622 from being damaged when the third sacrificial layer 721 is removed. This implementation is explained taking the component material of the second dielectric layer 622 being silicon oxide and the component material of the third sacrificial layer 721 being silicon nitride as an example.

Continuing to refer to FIG. 14 and FIG. 15, after the second deck structure 720 is formed, a portion of the second deck structure 720 and a portion of the second sacrificial layer 730 are removed to form a second channel hole 752 and a second gate slit 762, the second channel hole 752 is connected with the first channel hole 751, the second channel hole 752 and the first channel hole 751 together constitute a channel hole 750, the second gate slit 762 is connected with the first gate slit 761, and the second gate slit 762 and the first gate slit 761 together constitute a gate slit 760.

In this operation, for example, a dry etching process may be adopted to remove a portion of the second deck structure 720 and a portion of the second sacrificial layer 730, to form the second channel hole 752 and the second gate slit 762. The second channel hole 752 penetrates through the second deck structure 720 and the second sacrificial layer 730, and the second channel hole 752 is connected with the first channel hole 751. The first channel hole 751 and the second channel hole 752 together constitute a channel hole 750. The second gate slit 762 penetrates through the second deck structure 720 and the second sacrificial layer 730, and the second gate slit 762 is connected with the first gate slit 761. The first gate slit 761 and the second gate slit 762 together constitute the gate slit 760.

After forming the second channel hole 752 and the second gate slit 762, the sacrificial material in the first channel hole 751 and the first gate slit 761 may be removed. In some examples, when the sacrificial material includes carbon, the process of removing the sacrificial material within the first channel hole 751 and the first gate slit 761 may include ashing to remove all of the sacrificial material within the first channel hole 751 and the first gate slit 761.

In some other implementations, referring to FIG. 15 and FIG. 16, the operation of forming the first deck structure 710 may include forming a first sub-deck structure 7101.

In this operation, for example, the first dielectric layer 612 and the first sacrificial layer 711 may be alternately formed on the semiconductor layer by using a deposition process to form the first sub-deck structure 7101.

After the first sub-deck structure 7101 is formed, a portion of the first sub-deck structure 7101 is removed to form a third channel hole 753 and a third gate slit 763, the third channel hole 753 and the third gate slit 763 both penetrate through the first sub-deck structure 7101, and the third gate slit 763 is located on a side of the third channel hole 753 along the second direction Y.

In this operation, referring to FIG. 16, for example, a dry etching process may be adopted to remove a portion of the first sub-deck structure 7101 to form a third channel hole 753 and a third gate slit 763.

After forming the third channel hole 753 and the third gate slit 763, a deposition process may be adopted to fill a sacrificial material (such as carbon) within the third channel hole 753 and the third gate slit 763, so as to continue to form the second sub-deck structure 7102 on the first sub-deck structure 7101 in a subsequent manufacturing operation.

Still referring to FIG. 16, after forming the third channel hole 753 and the third gate slit 763, the method further includes: forming a second sub-deck structure 7102, where the second sub-deck structure 7102 and the first sub-deck structure 7101 are stacked along the first direction X. The second sub-deck structure 7102 and the first sub-deck structure 7101 together constitute the first deck structure 710.

In this operation, for example, a deposition process may be adopted to alternately form the first dielectric layer 612 and the first sacrificial layer 711 on the first sub-deck structure 7101 to form the second sub-deck structure 7102.

Still referring to FIG. 16, after the second sub-deck structure 7102 is formed, a second sacrificial layer 730 may be formed on the second sub-deck structure 7102 by a deposition process. After the second sacrificial layer 730 is formed, the second deck structure 720 is formed. Forming the second deck structure 720 may include forming a third sub-deck structure 7201, and the third sub-deck structure 7201 and the second sacrificial layer 730 are stacked along the first direction X.

In this operation, as shown in FIG. 16, a second dielectric layer 622 and a third sacrificial layer 721 may be alternately formed on a side of the second sacrificial layer 730 away from the second sub-deck structure 7102 by using a deposition process, to form a third sub-deck structure 7201.

As shown in FIG. 16, after forming the third sub-deck structure 7201, the method further includes: removing a portion of the second sub-deck structure 7102, a portion of the second sacrificial layer 730, and a portion of the third sub-deck structure 7201 to form a fourth channel hole 754 and a fourth gate slit 764, where the fourth channel hole 754 penetrates through the second sub-deck structure 7102, the second sacrificial layer 730, and the third sub-deck structure 7201 to the third channel hole 753. The fourth gate slit 764 penetrates through the second sub-deck structure 7102, the second sacrificial layer 730, and the third sub-deck structure 7201 to the third gate slit 763.

In this operation, for example, a dry etching process may be adopted to remove a portion of the second sub-deck structure 7102, a portion of the second sacrificial layer 730, and a portion of the third sub-deck structure 7201 to form a fourth channel hole 754 and a fourth gate slit 764.

After the fourth channel hole 754 and the fourth gate slit 764 are formed, a deposition process may be adopted to fill a sacrificial material (such as carbon) within the fourth channel hole 754 and the fourth gate slit 764, so as to continue to form the fourth sub-deck structure 7202 on the third sub-deck structure 7201 in a subsequent manufacturing operation. In addition, the sacrificial material filled in the fourth channel hole 754 and the fourth gate slit 764 may be the same as the sacrificial material filled in the third channel hole 753 and the third gate slit 763, which is beneficial for subsequent removal all together in one process operation.

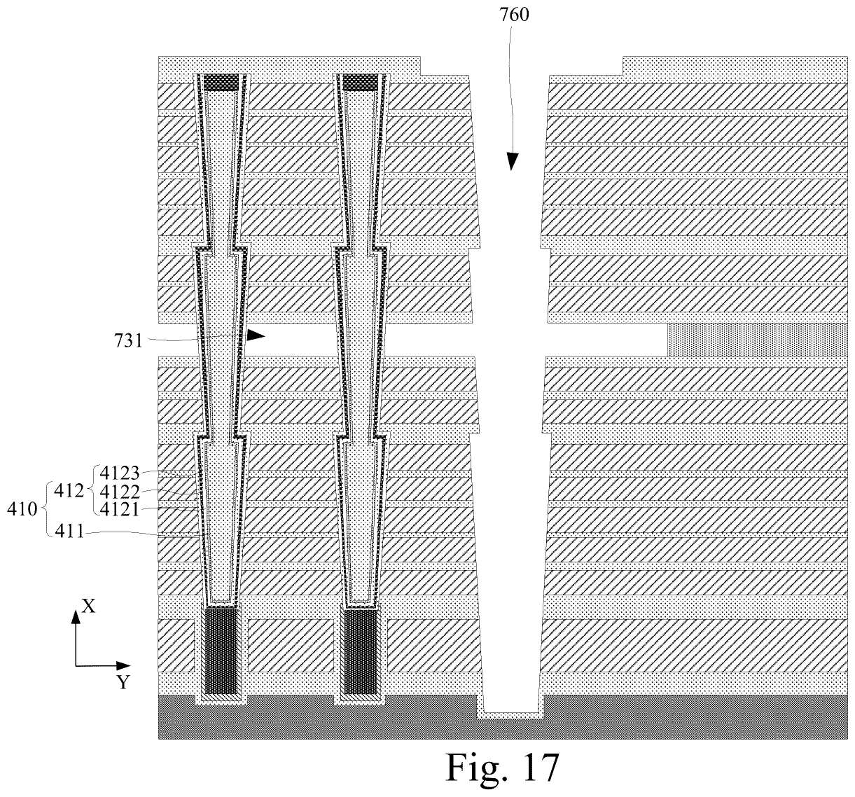

Referring to FIG. 16 and FIG. 17, after forming the fourth channel hole 754 and the fourth gate slit 764, the method further includes: forming a fourth sub-deck structure 7202, where the fourth sub-deck structure 7202 and the third sub-deck structure 7201 are stacked along the first direction X.

In this operation, for example, a deposition process may be adopted to alternately form the second dielectric layer 622 and the third sacrificial layer 721 on a side of the third sub-deck structure 7201 away from the second sacrificial layer 730 to form the fourth sub-deck structure 7202.

Still referring to FIG. 16 and FIG. 17, after forming the fourth sub-deck structure 7202, the method further includes: removing a portion of the fourth sub-deck structure 7202 to form a fifth channel hole 755 and a fifth gate slit 765, where the fifth channel hole 755 penetrates through the fourth sub-deck structure 7202 to the fourth channel hole 754 and is connected to the fourth channel hole 754, and the third channel hole 753, the fourth channel hole 754, and the fifth channel hole 755 together constitute a channel hole 750. The fifth gate slit 765 penetrates through the fourth sub-deck structure 7202 to the fourth gate slit 764, and the third gate slit 763, the fourth gate slit 764 and the fifth gate slit 765 together constitute the gate slit 760.

In this operation, a dry etching process may be adopted to remove a portion of the fourth sub-deck structure 7202 to form the fifth channel hole 755 and the fifth gate slit 765. Subsequently, the sacrificial materials in the third channel hole 753, the fourth channel hole 754, the third gate slit 763, and the fourth gate slit 764 are removed, for example, when the sacrificial material includes carbon, the process of removing the sacrificial material may include ashing to remove all the sacrificial materials in the third channel hole 753, the fourth channel hole 754, the third gate slit 763, and the fourth gate slit 764, such that the third channel hole 753, the fourth channel hole 754, and the fifth channel hole 755 are connected and together constitute the channel hole 750, and such that the third gate slit 763, the fourth gate slit 764, and the fifth gate slit 765 are connected and together constitute the gate slit 760.

Referring to FIG. 16 and FIG. 17, after forming the channel hole, the method further includes forming a channel structure 410 penetrating through the first deck structure 710, the second sacrificial layer 730, and the second deck structure 720.

In this operation, referring to FIG. 16 and FIG. 17, forming the channel structure 410 includes sequentially forming a functional layer 412 and a channel layer 411 in the channel hole 750, and the functional layer 412 is disposed around a portion of the channel layer 411. For example, the functional layer 412 and the channel layer 411 may be sequentially formed in the channel hole 750 by using one or more thin film deposition processes including, but not limited to, PVD, CVD, and ALD, and the functional layer 412 is disposed around the channel layer 411. Forming the functional layer 412 in the channel hole 750 includes sequentially forming a blocking layer 4123, a storage layer 4122 and a tunneling layer 4121 in the channel hole 750. In some examples, the material of the tunneling layer 4121 may include, but is not limited to, one or more of silicon oxide and silicon oxynitride. The material of the blocking layer 4123 may include one or more of silicon oxide, silicon nitride, and a high dielectric constant material. The material of the storage layer 4122 may include silicon nitride, or may include other materials suitable for storing carriers. The material of the channel layer 411 may include, but is not limited to, amorphous silicon, polycrystalline silicon, or monocrystalline silicon.

After the channel structure 410 is formed, the second sacrificial layer 730 is replaced with the source layer SL.

Referring to FIG. 16 and FIG. 17, this operation includes removing a portion of the second sacrificial layer 730 to form a filling space 731 which exposes a portion of the functional layer 412. In some examples, a wet etching process may be adopted to remove a portion of the second sacrificial layer 730, for example, by injecting an etchant into the gate slit 760.

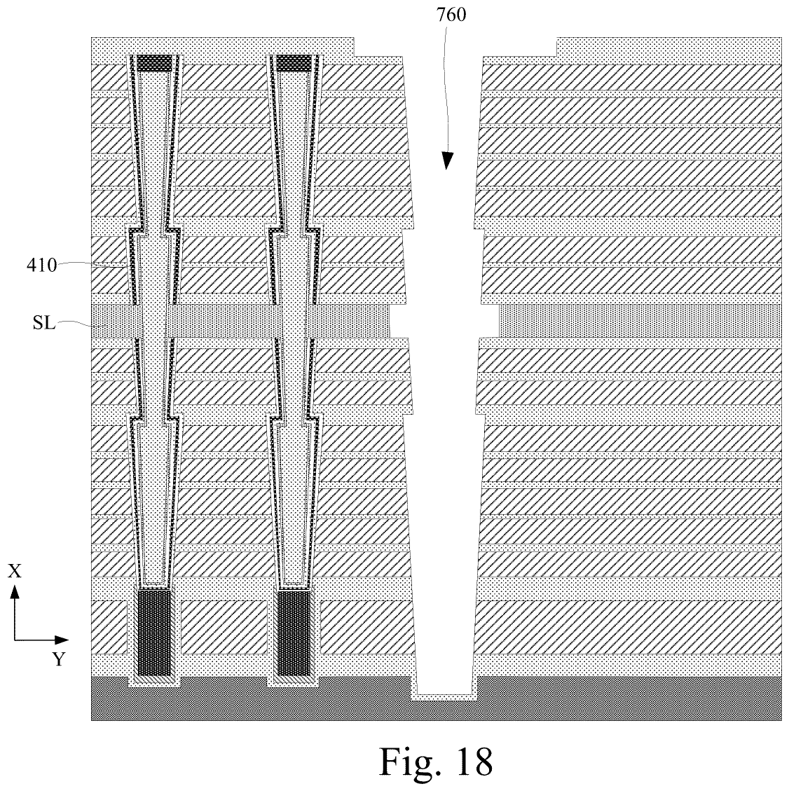

Referring to FIG. 16, FIG. 17, and FIG. 18, after forming the filling space 731, the method further includes: removing a portion of the functional layer 412 through the filling space 731, to separate the functional layer 412 into a first portion 4124 and a second portion 4125 (referring to FIG. 5), where the first portion 4124 penetrates through the first deck structure 710, and the second portion 4125 penetrates through the second deck structure 720.

In this operation, for example, a wet etching process may be adopted to remove the functional layer 412 exposed in the filling space 731 and expose a portion of the channel layer 411 by injecting an etchant into the gate slit 760 and the filling space 731.

After a portion of the functional layer 412 is removed through the filling space 731, the filling space 731 may be filled with a semiconductor material, such as polysilicon, by using one or more thin film deposition processes including, but not limited to, PVD, CVD, and ALD, to form the source layer SL. Also, the source layer SL is connected to the channel layer 411 exposed in the filling space 731.

Here, it should be noted that in the operation of forming the second sacrificial layer 730, a polysilicon material may be deposited by a deposition process to form the second sacrificial layer 730. It may be construed that the component material of the second sacrificial layer 730 may be the same as the component material of the source layer SL. Therefore, after the source layer SL is formed in the filling space 731, the source layer SL is connected to the second sacrificial layer 730 which is not removed, and in this case, the second sacrificial layer 730 which is not removed is also considered as the source layer SL.

After the source layer SL is formed, the first sacrificial layer 711 is replaced with the first gate layer 611, and the third sacrificial layer 721 is replaced with the second gate layer 621.

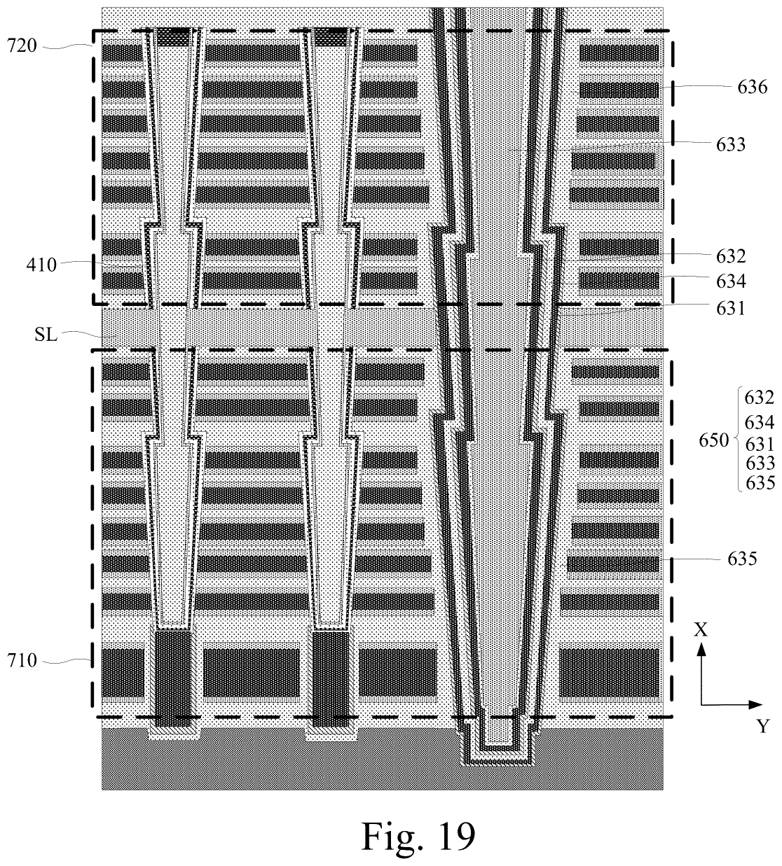

Referring to FIG. 18 and FIG. 19, in this operation, the first sacrificial layer 711 and the third sacrificial layer 721 may be removed through the gate slit 760 by using a wet etching process, and then by using one or more thin film deposition processes including, but not limited to, PVD, CVD, and ALD, a conductive material may be deposited at the position where the original first sacrificial layer 711 is located to form the first gate layer 611, and a conductive material may be deposited at the position where the original third sacrificial layer 721 is located to form the second gate layer 621. In some examples, the conductive material includes, but is not limited to, one or more of tungsten (W), cobalt (Co), copper (Cu), aluminum (Al), polysilicon, doped silicon, and silicide, or may be other suitable conductive materials. In some examples, the component material of the first gate layer 611 may include a doped polysilicon layer. The polysilicon may be doped to a desired doping concentration with a suitable dopant so that the polysilicon may become a conductive material for the first gate layer 611.

After the first sacrificial layer 711 is replaced with the first gate layer 611, and the third sacrificial layer 721 is replaced with the second gate layer 621, the first deck structure 710 constitutes the first stack structure 610, and the second deck structure 720 constitutes the second stack structure 620.

The semiconductor device 600 produced by the above method of manufacturing shortens the length, in the first direction X, of the channel structure 410 to be driven by the source layer SL, which can improve the problem of the increase of the resistance and the decrease of the voltage difference of the channel structure 410 caused by the increase of the length of the channel structure 410, and is beneficial for increasing the current intensity in the channel structure 410, thereby improving the device performance such as the storage speed and the response speed of the semiconductor device 600.

At operation S2, the method may include forming a gate isolation structure, where the gate isolation structure penetrates through the first stack structure, the source layer and the second stack structure along the first direction, the gate isolation structure includes a first connection portion, a second connection portion and a first isolation portion, the first connection portion is disposed around the second connection portion, the first isolation portion is located between the first connection portion and the second connection portion, and the first connection portion is connected to the source layer.

Referring to FIG. 18 and FIG. 19, this operation may include sequentially forming a first connection portion 631, a first isolation portion 633, a second connection portion 632 and a second isolation portion 634 in the gate slit 760, the second connection portion 632 is disposed around the second isolation portion 634, the first connection portion 631 is disposed around the second connection portion 632, the first isolation portion 633 is located between the first connection portion 631 and the second connection portion 632, and the first connection portion 631 is connected to the source layer SL.

In some examples, before forming the first connection portion 631 in the gate slit 760, the method further includes: forming a third isolation portion 635 and a fourth isolation portion 636 in the gate slit 760, where the third isolation portion 635 covers the first gate layer 611, and the fourth isolation portion 636 covers the second gate layer 621.

It should be noted that after the filling space 731 is filled with the semiconductor material to form the source layer SL, the sidewall of the gate slit 760 may be adhered with the semiconductor material, and in order to facilitate subsequent removal of the first sacrificial layer 711 through the gate slit 760, an etching process, such as a wet etching process, may be adopted to remove the semiconductor material adhered to the sidewall of the gate slit 760. In the above operation, a portion of the source layer SL may be removed.

After the first sacrificial layer 711 is replaced with the first gate layer 611 and the third sacrificial layer 721 is replaced with the second gate layer 621, the sidewall of the gate slit 760 is adhered with the conductive material. In order to isolate the first gate layer 611 from the second gate layer 621, an etching process, such as a wet etching process, may be adopted to remove the conductive material adhered to the sidewalls of the gate slit 760 through the gate slit 760, and to remove a portion of the first gate layer 611 and a portion of the second gate layer 621 along the second direction. Here, the size of the removed first gate layer 611 in the second direction Y is greater than the size of the removed source layer SL in the second direction Y, and the size of the removed second gate layer 621 in the second direction Y is greater than the size of the removed source layer SL in the second direction Y.

In this operation, for example, an insulating material may be deposited in the gate slit 760 by using one or more thin film deposition processes including, but not limited to, PVD, CVD, and ALD, to form the third isolation portion 635 and the fourth isolation portion 636. Since the size of the removed first gate layer 611 in the second direction Y is larger than the size of the removed source layer SL in the second direction Y, after the insulating material is deposited in the gate slit 760, in the second direction Y, the insulating material on a side of the first gate layer 611 is thicker than the insulating material on the source layer SL. Based on the same reason, after the insulating material is deposited in the gate slit 760, in the second direction Y, the insulating material on a side of the second gate layer 621 is thicker than the insulating material on a side of the source layer SL. Through the above operations, it is beneficial for removing the insulating material on a side of the source layer, and retaining a portion of the insulating material on a side of the first gate layer 611 to form the third isolation portion 635; and retaining a portion of the insulating material on a side of the second gate layer 621 to form the fourth isolation portion 636.

Then, a conductive material is deposited in the gate slit 760 by a deposition process to form the first connection portion 631 which is connected to the source layer SL, then an insulating material is deposited in the gate slit 760 by a deposition process to form the first isolation portion 633, and then a conductive material is deposited in the gate slit 760 by a deposition process to form the second connection portion 632.

At operation S3, the method may include forming a first bit line, where the first bit line is located on a side of the first stack structure away from the second stack structure, the first bit line extends along a second direction, the gate isolation structure extends along a third direction, the first bit line is connected to one end of the second connection portion, the second direction intersects with the first direction, and the third direction intersects a plane where the first direction and the second direction are located.

Referring to FIG. 19 and FIG. 11, in this operation, for example, a first contact 701 may be formed at the end of the second connection portion 632 away from the second stack structure 620 by a deposition process, and the first contact 701 is connected to the second connection portion 632. The first bit line BL-1 is formed on a side of the first contact 701 away from the second connection portion 632 by a deposition process, and the first bit line BL-1 is connected to the first contact 701, and the first bit line BL-1 may be connected to the second connection portion 632 through the first contact 701.

At operation S4, the method may include forming a second bit line, where the second bit line is located on a side of the second stack structure away from the first stack structure, and the second bit line extends along the second direction and is connected to the other end of the second connection portion.

Referring to FIG. 19 and FIG. 11, in this operation, for example, a second contact 702 may be formed at the end of the second connection portion 632 away from the first stack structure 610 by a deposition process, and the second contact 702 is connected to the second connection portion 632. A second bit line BL-2 is formed on a side of the second contact 702 away from the second connection portion 632 by a deposition process, and the second bit line BL-2 is connected to the second contact 702, and the second bit line BL-2 may be connected to the second connection portion 632 through the second contact 702. The first bit line BL-1 and the second bit line BL-2 are connected through the second connection portion 632.

According to the semiconductor device 600 obtained by the above manufacturing method, the source layer SL is led out through the gate isolation structure 630, and the first bit line BL-1 and the second bit line BL-2 are connected, which can simplify the structural design of the semiconductor device 600, and is beneficial for reducing the size of the semiconductor device 600 in the second direction Y and increasing the storage density of the semiconductor device 600.

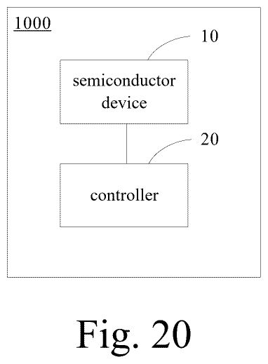

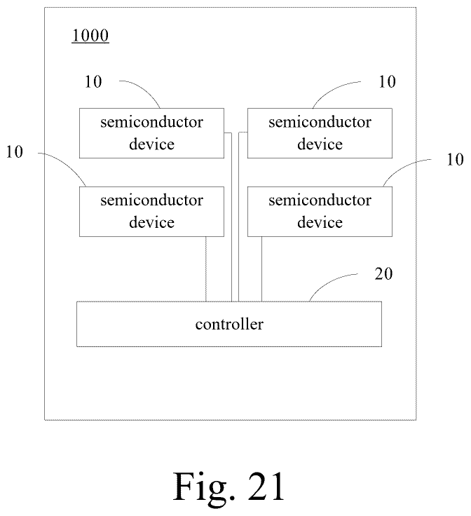

FIG. 20 is a block diagram of a memory system according to some implementations. FIG. 21 is a block diagram of a memory system according to further implementations. Referring to FIG. 20 and FIG. 21, some implementations of the present disclosure further provide a memory system 1000 including a controller 20 and the semiconductor device 600 provided by the above implementations. The controller 20 is coupled to the semiconductor device 600 to control the semiconductor device 600 to store data.

The memory system 1000 may be integrated into various types of storage devices, for example, included in a same package (for example, a universal flash storage (UFS) package or an embedded multimedia card (eMMC) package). That is, the memory system 1000 may be applied to and packaged into different types of electronic products, for example, a mobile phone (such as a mobile phone), a desktop computer, a tablet computer, a notebook computer, a server, an in-vehicle device, a game console, a printer, a positioning device, a wearable device, a smart sensor, a mobile power supply, a virtual reality (VR) device, an augmented reality (AR) device, or any other suitable electronics having a memory therein.

In some implementations, referring to FIG. 20, the memory system 1000 includes a controller 20 and one semiconductor device 600, and the memory system 1000 may be integrated into a memory card. In some examples, the semiconductor device 600 may be a memory having a three-dimensional structure (3D NAND).

The memory card includes any one of a PC card (International Association of Personal Computer Memory Cards, PCMCIA), a compact flash (CF) card, a smart media (SM) card, a memory stick, a multimedia card (MMC), a secure digital memory card (SD device) card, and a UFS.

In some other implementations, referring to FIG. 21, the memory system 1000 includes a controller 20 and a plurality of semiconductor devices 600, and the memory system 1000 is integrated into solid state drives (SSD devices).

In the memory system 1000, in some implementations, the controller 20 is configured for operating in a low duty cycle environment, such as an SD device card, a CF card, a Universal Serial Bus (USB) flash drive, or other media for use in electronics such as personal calculators, digital cameras, mobile phones, etc.

In other implementations, the controller 20 is configured for operating in a high duty cycle environment SSD device or eMMC for data storage of mobile devices (such as smartphones, tablets, and laptops) and enterprise storage arrays.

In some implementations, the controller 20 may be configured to manage data stored in the semiconductor device 600 and communicate with an external device (e.g., a host). In some implementations, the controller 20 may also be configured to control operations of the semiconductor device 600, such as read, erase, and program operations. In some implementations, the controller 20 may be further configured to manage various functions regarding data stored or to be stored in the semiconductor device 600, including at least one of bad block management, garbage collection, logical-to-physical address translation, wear leveling. In some implementations, the controller 20 is further configured to process error correction codes on data read from or written to the semiconductor device 600.

Of course, the controller 20 may also perform any other suitable functions, such as formatting the semiconductor device 600; for example, the controller 20 may communicate with an external device (e.g., a host) through at least one of various interface protocols.

It should be noted that the interface protocol includes at least one of a USB protocol, an MMC protocol, a peripheral component interconnect (PCI) protocol, a PCI express (PCI-E) protocol, an advanced technology attachment (ATA) protocol, a serial ATA protocol, a parallel ATA protocol, a small computer small interface (SCSI) protocol, an enhanced small disk interface (ESDI) protocol, an integrated drive electronics (IDE) protocol, and a Firewire protocol.

The controller 20 in the foregoing implementation may be, for example, a central processing unit (CPU), a general-purpose processor, a digital signal processor (DSP), an application-specific integrated circuit (ASIC), a field programmable gate array (FPGA) or another programmable logic device, a transistor logic device, a hardware component, or any combination thereof.

In this implementation, the memory system 1000 includes the semiconductor device 600 provided in some implementations described above, which is beneficial for increasing the storage density of the memory system 1000 and improving the device performance such as the response speed of the memory system 1000.

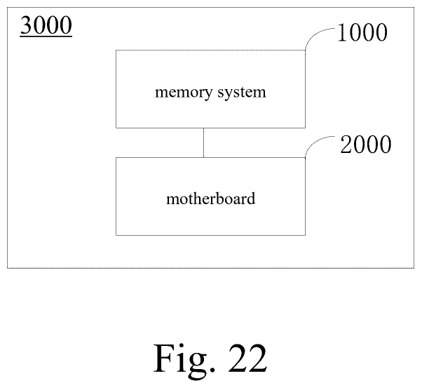

Some implementations of the present disclosure further provide electronics. FIG. 22 is a block diagram of electronics according to some implementations. As shown in FIG. 22, the electronics 3000 includes a motherboard 2000 and the memory system 1000 provided in some implementations described above. The motherboard 2000 is electrically connected to the memory system 1000. In addition, the electronics 3000 may further include at least one of a central processing unit (CPU) and a cache.

In some examples, the electronics 3000 may be any one of a mobile phone, a desktop computer, a tablet computer, a notebook computer, a server, an in-vehicle device, a wearable device (for example, a smart watch, a smart bracelet, or smart glasses), a mobile power supply, a game console, a digital multimedia player, or the like.

In this implementation, the electronics 3000 may include the memory system 1000 provided in some implementations described above, which is beneficial for increasing the storage density of the electronics 3000, is beneficial for the development of the electronics 3000 in the direction of large capacity and small volume, and is beneficial for improving the device performance such as the response speed of the electronics.

The above description is only specific implementations of the present disclosure, but the protection scope of the present disclosure is not limited thereto, and any changes or substitutions that can be easily conceivable by those skilled in the art within the technical scope of the present disclosure should be covered within the protection scope of the present disclosure. Therefore, the protection scope of the present disclosure shall be defined by the protection scope of the claims.

What is claimed is:

1. A semiconductor device, comprising:
a first stack structure, a source layer, and a second stack structure sequentially stacked along a first direction;
a first bit line and a second bit line, where the first bit line is located on a side of the first stack structure away from the second stack structure, the second bit line is located on a side of the second stack structure away from the first stack structure, both the first bit line and the second bit line extend along a second direction, and the second direction intersects with the first direction; and
a gate isolation structure that extends along a third direction and penetrates through the first stack structure, the source layer, and the second stack structure along the first direction, where the third direction intersects with a plane in which the first direction and the second direction are located, the gate isolation structure includes a first connection portion, a second connection portion, and a first isolation portion, the first connection portion is disposed around the second connection portion in a plane parallel to the second direction and the third direction, the first isolation portion is located between the first connection portion and the second connection portion, the first connection portion is connected to the source layer, and two ends of the second connection portion along the first direction are respectively connected to the first bit line and the second bit line.

2. The semiconductor device of claim 1, wherein the gate isolation structure comprises:
a second isolation portion, wherein the second connection portion is disposed around the second isolation portion in a plane parallel to the second direction and the third direction.

3. The semiconductor device of claim 1, wherein the gate isolation structure comprises:
a third isolation portion and a fourth isolation portion located on two opposite sides of the source layer, wherein the third isolation portion is located between the first connection portion and the first stack structure, and the fourth isolation portion is located between the first connection portion and the second stack structure.

4. The semiconductor device of claim 1, wherein the gate isolation structure comprises:
a plurality of gate isolation structures, wherein the plurality of gate isolation structures are arranged in a plurality of columns along the second direction and arranged in a plurality of rows along the third direction, and two adjacent rows of the gate isolation structures are staggered in the third direction.

5. The semiconductor device of claim 4, wherein the first bit line comprises:
a plurality of first bit lines, the plurality of first bit lines are sequentially arranged at intervals along the third direction, and one first bit line is connected to one end of one second connection portion; and
the second bit line includes a plurality of plurality of second bit lines, wherein the plurality of second bit lines are sequentially arranged at intervals along the third direction, and one second bit line is connected to the other end of the one second connection portion.

6. The semiconductor device of claim 5, further comprising:
a dielectric structure, wherein the dielectric structure penetrates through the first stack structure, the source layer, and the second stack structure along the first direction, and at least one dielectric structure is disposed between two adjacent gate isolation structures in the third direction.

7. The semiconductor device of claim 6, wherein, in a plane parallel to the second direction and the third direction, a contour edge of a cross section of the dielectric structure includes at least one arc-shaped edge.

8. The semiconductor device of claim 5, further comprises:
a plurality of channel structures penetrating through the first stack structure, the source layer, and the second stack structure,
wherein the plurality of channel structures are arranged in a plurality of rows along the third direction, the plurality of channel structures are arranged in a plurality of columns along the second direction, and two adjacent rows of the channel structures are staggered in the third direction,
wherein a plurality of rows of the channel structures are disposed between two adjacent rows of the gate isolation structures along the second direction, and
wherein among the plurality of rows of the channel structures, one first bit line is connected to at least one of the channel structures.

9. The semiconductor device of claim 8, wherein the channel structure comprises:
a channel layer and a functional layer, and the functional layer is disposed around a portion of the channel layer;
the channel layer penetrates through the first stack structure, the source layer, and the second stack structure along the first direction and is in contact with the source layer; and
the functional layer includes a first portion and a second portion located on two opposite sides of the source layer, the first portion penetrates through the first stack structure and is in contact with the source layer, and the second portion penetrates through the second stack structure and is in contact with the source layer.

10. The semiconductor device of claim 5, wherein:
the plurality of first bit lines constitute a plurality of first bit line groups, and the first bit line group includes at least two adjacent first bit lines, and
in the first direction, respective first bit lines in the first bit line group overlap with respective gate isolation structures located in a same column.

11. The semiconductor device of claim 10, wherein one gate isolation structure in a column of the plurality of gate isolation structures overlapping the first bit line group is connected to one first bit line in the first bit line group.

12. The semiconductor device of claim 11, wherein the plurality of gate isolation structures have a same size in the third direction.

13. The semiconductor device of claim 1, further comprising:
a first contact, wherein, in the first direction, two ends of the first contact are respectively connected to the first bit line and the second connection portion; and
a second contact, wherein, in the first direction, two ends of the second contact are respectively connected to the second bit line and the second connection portion.

14. The semiconductor device of claim 1, wherein:
the first stack structure includes first gate layers and first dielectric layers alternately stacked along the first direction, and the second stack structure includes second gate layers and second dielectric layers alternately stacked along the first direction, and
the semiconductor device further includes a plurality of connection structures located on a side of the first stack structure and the second stack structure, one of the connection structures is connected with at least one of the first gate layers, and one of the connection structures is connected with at least one of the second gate layers.

15. A method of manufacturing a semiconductor device, comprising:
forming a first stack structure, a source layer, and a second stack structure sequentially stacked along a first direction;
forming a gate isolation structure, wherein the gate isolation structure penetrates through the first stack structure, the source layer and the second stack structure along the first direction, the gate isolation structure includes a first connection portion, a second connection portion and a first isolation portion, the first connection portion is disposed around the second connection portion, the first isolation portion is located between the first connection portion and the second connection portion, and the first connection portion is connected to the source layer;
forming a first bit line, wherein the first bit line is located on a side of the first stack structure away from the second stack structure, the first bit line extends along a second direction, the gate isolation structure extends along a third direction, the first bit line is connected to one end of the second connection portion, the second direction intersects with the first direction, and the third direction intersects a plane where the first direction and the second direction are located; and
forming a second bit line, wherein the second bit line is located on a side of the second stack structure away from the first stack structure, the second bit line extends along the second direction, and the second bit line is connected to the other end of the second connection portion.

16. The method of claim 15, wherein the forming the first stack structure, the source layer, and the second stack structure sequentially stacked along the first direction comprises:
forming a first deck structure, wherein the first deck structure includes a plurality of first sacrificial layers and a plurality of first dielectric layers alternately stacked along a first direction;
forming a second sacrificial layer, wherein the second sacrificial layer and the first deck structure are stacked along the first direction;
forming a second deck structure, wherein the second deck structure is located on a side of the second sacrificial layer away from the first deck structure, and the second deck structure includes a plurality of third sacrificial layers and a plurality of second dielectric layers alternately stacked along the first direction;
forming a channel structure, wherein the channel structure penetrates through the first deck structure, the second sacrificial layer and the second deck structure;
replacing the second sacrificial layer with a source layer, wherein the source layer is connected to the channel structure; and
replacing the first sacrificial layer with a first gate layer, and replacing the third sacrificial layer with a second gate layer.

17. The method of claim 16, wherein:
after forming the first deck structure and before forming the second sacrificial layer, the method further comprises:
removing a portion of the first deck structure to form a first channel hole and a first gate slit, wherein both the first channel hole and the first gate slit penetrates through the first deck structure, and the first gate slit is located on a side of the first channel hole along the second direction; and
after forming the second deck structure and before forming the channel structure, the method further comprises:
removing a portion of the second deck structure and a portion of the second sacrificial layer to form a second channel hole and a second gate slit, wherein the second channel hole penetrates through the second deck structure to the first channel hole, the second channel hole and the first channel hole together constitute a channel hole, the second gate slit penetrates through the second deck structure to the first gate slit, and the second gate slit and the first gate slit together constitute a gate slit.

18. The method of claim 16, wherein the forming the first deck structure comprises:
forming a first sub-deck structure;
removing a portion of the first sub-deck structure to form a third channel hole and a third gate slit, wherein the third channel hole and the third gate slit both penetrate through the first sub-deck structure, and the third gate slit is located on a side of the third channel hole along the second direction; and
forming a second sub-deck structure, wherein the second sub-deck structure and the first sub-deck structure is stacked along the first direction; and
wherein forming the second deck structure includes:
forming a third sub-deck structure;
removing a portion of the second sub-deck structure, a portion of the second sacrificial layer, and a portion of the third sub-deck structure to form a fourth channel hole and a fourth gate slit, wherein the fourth channel hole is connected with the third channel hole, and the fourth gate slit is connected with the fourth channel hole;
forming a fourth sub-deck structure, wherein the fourth sub-deck structure and the third sub-deck structure are stacked along the first direction; and
removing a portion of the fourth sub-deck structure to form a fifth channel hole and a fifth gate slit, wherein the fifth channel hole penetrate through the fourth sub-deck structure to the fourth channel hole, wherein the third channel hole, the fourth channel hole and the fifth channel hole together constitute a channel hole, the fifth gate slit penetrates through the fourth sub-deck structure to the fourth gate slit, and the third gate slit, and the fourth gate slit and the fifth gate slit together constitute a gate slit.

19. The method of claim 17, wherein:
the forming the channel structure comprises:
sequentially forming a functional layer and a channel layer in the channel hole, the functional layer is disposed around a portion of the channel layer, and
the replacing the second sacrificial layer with the source layer comprises:
removing a portion of the second sacrificial layer to form a filling space, wherein the filling space exposes a portion of the functional layer;
removing a portion of the functional layer through the filling space; and
forming the source layer in the filling space.

20. A memory system, including:
a semiconductor device; and
a controller coupled to the semiconductor device to control the semiconductor device to store data, wherein the semiconductor device comprises:
a first stack structure, a source layer and a second stack structure sequentially stacked along a first direction;
a first bit line and a second bit line, wherein the first bit line is located on a side of the first stack structure away from the second stack structure, the second bit line is located on a side of the second stack structure away from the first stack structure, both the first bit line and the second bit line extend along a second direction, and the second direction intersects with the first direction; and
a gate isolation structure that extends along a third direction and penetrates through the first stack structure, the source layer and the second stack structure along the first direction, wherein the third direction intersects with a plane where the first direction and the second direction are located, the gate isolation structure includes a first connection portion, a second connection portion and a first isolation portion, the first connection portion is disposed around the second connection portion in a plane parallel to the second direction and the third direction, the first isolation portion is located between the first connection portion and the second connection portion, the first connection portion is connected to the source layer, and two ends of the second connection portion along the first direction are respectively connected to the first bit line and the second bit line.
